(19) United States
(12) Patent Application Publication
(10) Pub. No.: US 2011/0227058 A1
(43) Pub. Date: Sep. 22, 2011

(54) ORGANIC ELECTROLUMINESCENCE ELEMENT

(76) Inventors: Kensuke Masui, Kanagawa (JP); Masayuki Hayashi, Kanagawa (JP)

(21) Appl. No.: 13/132,046

(22) PCT Filed: Dec. 25, 2009
(86) PCT No.: PCT/JP2009/071557

§ 371 Date: May 31, 2011

(30) Foreign Application Priority Data
Jan. 22, 2009 (JP) 2009-012389

(51) Int. Cl. H01L 51/54

(52) U.S. Cl. 257/40; 257/E51.018

(57) ABSTRACT

An organic electroluminescence element including at least one organic layer including a light emitting layer, between an anode and a cathode, wherein at least one layer of the at least one organic layer contains at least one selected from specific nitrogen-containing heterocyclic derivatives, and at least one layer of the at least one organic layer contains a specific electron-transporting phosphorous light emitting material.

### BACKGROUND OF THE INVENTION

1. Field of the Invention

The present invention relates to an organic electroluminescence element (which may be, hereinafter, referred to as “organic electroluminescent element”, or “organic EL element)”.

2. Background Art

Organic electroluminescence elements have advantages of self-light emission and high-speed responsiveness and are expected to be used in flat panel display devices. Particularly, since a two-layered (multi-layered) organic EL element in which a hole-transporting organic thin film (hole transporting layer) and an electron transporting organic thin film (electron transporting layer) are laminated was reported, large-area light emitting element which emit light at a low voltage of 10 V or lower have attracted great interest. A multi-layered organic EL element basically includes a positive electrode, a hole transporting layer, a light emitting layer, an electron transporting layer and a negative electrode, among which the hole transporting layer or the electron transporting layer may function as the light emitting layer as in the case with the two-layered organic EL element.

In order to simultaneously achieve low-voltage supply and high light-emission efficiency in such organic EL elements, various studies have been made. For example, PTL 1 describes that by using, as a highly electron-transporting material, a specific nitrogen-containing heterocyclic derivative in an electron injection layer and an electron transporting layer, low-voltage supply and high light-emission efficiency can be achieved. Surely, when the highly electron-transporting material described in PTL 1 is used, the driving voltage can be reduced, but there is a problem that when a phosphorescence emission material is used in a light emitting layer, it causes a reduction in light emission efficiency. This can be considered as follows. When a commonly used hole transporting material is used as a host material, most of phosphorescence emission materials are hole transportable, and when electrons are excessively injected into the light emitting layer, the flow of the electrons remains sluggish in the light emitting layer, the carrier balance between electrons and holes is off-balance, and as a result, the reduction in light emission efficiency occurs.

Although PTL 1 discloses examples of using fluorescence light emission elements, there is no description about examples using phosphorescence materials, there is no suggestion about problems with a reduction in light emission efficiency in the case where a phosphorescence emission material is used, and there is no disclosure nor suggestion about techniques required when a phosphorescence material is used.

### CITATION LIST

### Patent Literature

PTL 1 Japanese Patent Application Laid-Open (JP-A) No. 2004-217547

### SUMMARY OF INVENTION

The present invention aims to provide an organic electroluminescence element capable of reducing voltage of driving voltage and maintaining high light emission efficiency.

### SOLUTION TO PROBLEM

The present inventors carried out extensive studies and examinations to solve the above-mentioned problems and have found that by using a phosphorescence light emitting material having high electron-transportability in combination with a high electron transporting material, the flow of electrons in a light emitting layer is increased, the carrier balance of holes with electrons is improved and thereby the voltage can be reduced and high efficiency can be simultaneously achieved, and particularly when a phosphorescence light emitting material of a platinum complex compound containing a tetradentate ligand is used, high efficiency and a low driving voltage can be achieved.

The present invention has been made based on the present inventors' findings, and means for solving the above-mentioned problems are as follows:

<1> An organic electroluminescence element including:

at least one organic layer including a light emitting layer, between an anode and a cathode,

wherein at least one layer of the at least one organic layer contains at least one selected from nitrogen-containing heterocyclic derivatives represented by General Formula (1) below, and at least one layer of the at least one organic layer contains an electron-transporting phosphorous light emitting material represented by General Formula (2) below,

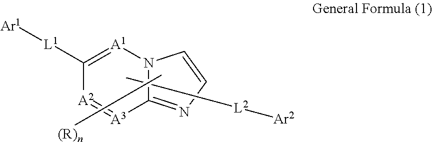

where A¹ to A³ each independently represent a nitrogen atom or a carbon atom, Ar¹ represents a substituted or unsubstituted aryl group having nucleus carbon atoms of 6 to 60 or a substituted or unsubstituted heteroaryl group having nucleus carbon atoms of 3 to 60, Ar² represents a hydrogen atom, a substituted or unsubstituted aryl group having nucleus carbon atoms of 6 to 60, a substituted or unsubstituted heteroaryl group having nucleus carbon atoms of 3 to 60, a substituted or unsubstituted alkyl group having 1 to 20 carbon atoms or a substituted or unsubstituted alkoxy group having 1 to 20 carbon atoms, wherein one of Ar¹ and Ar² is a substituted or unsubstituted condensed ring group having 10 to 60 nucleus carbon atoms or a substituted or unsubstituted monohetero condensed ring group having 3 to 60 nucleus carbon atoms; L¹ and L² each independently represent a single bond, a substituted or unsubstituted arylene group having 6 to 60 nucleus carbon atoms, a substituted or unsubstituted heteroarylene group having 3 to 60 nucleus carbon atoms or a substituted or unsubstituted fluorenylene group; R represents a hydrogen atoms, a substituted or unsubstituted aryl group having 6 to 60 nucleus carbon atoms, a substituted or unsubstituted heteroaryl group having nucleus carbon atoms of 3 to 60, a substituted or unsubstituted alkyl group having 1 to 20 carbon atoms or a substituted or unsubstituted alkoxy group having 1 to 20 carbon atoms; and n is an integer of 0 to 5, when n is 2 or greater, a plurality of Rs may be different from or identical to each other, and adjacent R groups among the plurality of Rs may be bonded to form a carbocyclic aliphatic ring or a carbocyclic aromatic ring,

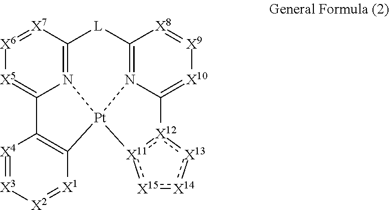

where X¹, X², X³ and X⁴ each independently represent a carbon atom or a nitrogen atom, and one or more selected from X¹, X², X³ and X⁴ represents or represent a nitrogen atom; X⁵, X⁶, X⁷, X⁸, X⁹ and X¹⁰ each independently represent a carbon atom or a nitrogen atom; X¹¹ and X¹² each independently represent a carbon atom or a nitrogen atom; X¹³, X¹⁴ and X¹⁵ each independently represent a carbon atom, a nitrogen atom, an oxygen atom or a sulfur atom, the number of nitrogen atoms contained in a five-membered ring skeleton represented by any one of X¹¹, X¹², X¹³, X¹⁴ and X¹⁵ is 2 or smaller; and L represents a single bond or a divalent linking group.

<2> The organic electroluminescence element according to <1>, wherein at least one selected from the nitrogen-containing heterocyclic derivatives represented by General Formula (1) is a nitrogen-containing heterocyclic derivative represented by General Formula (3) below,

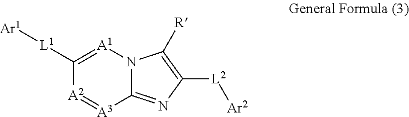

where A¹ to A³ each independently represent a nitrogen atom or a carbon atom, Ar¹ represents a substituted or unsubstituted aryl group having nucleus carbon atoms of 6 to 60 or a substituted or unsubstituted heteroaryl group having nucleus carbon atoms of 3 to 60, Ar² represents a hydrogen atom, a substituted or unsubstituted aryl group having nucleus carbon atoms of 6 to 60, a substituted or unsubstituted heteroaryl group having nucleus carbon atoms of 3 to 60, a substituted or unsubstituted alkyl group having 1 to 20 carbon atoms or a substituted or unsubstituted alkoxy group having 1 to 20 carbon atoms, wherein one of Ar¹ and Ar² is a substituted or unsubstituted condensed ring group having nucleus carbon atoms of 10 to 60 or a substituted or unsubstituted monohetero condensed ring group having nucleus carbon atoms of 3 to 60; L¹ and L² each independently represent a single bond, a substituted or unsubstituted arylene group having 6 to 60 nucleus carbon atoms, a substituted or unsubstituted heteroarylene group having 3 to 60 nucleus carbon atoms or a substituted or unsubstituted fluorenylene group; and R′ represents a hydrogen atom, a substituted or unsubstituted aryl group having 6 to 60 nucleus carbon atoms, a substituted or unsubstituted heteroaryl group having 3 to 60 nucleus carbon atoms, a substituted or unsubstituted alkyl group having 1 to 20 carbon atoms or a substituted or unsubstituted alkoxy group having 1 to 20 carbon atoms.

<3> The organic electroluminescence element according to <2>, wherein the nitrogen-containing heterocyclic derivative represented by General Formula (3) is a nitrogen-containing heterocyclic derivative represented by General Formula (4).

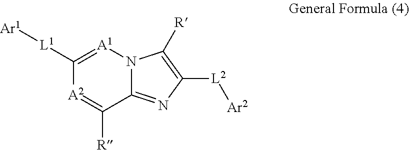

where A¹ and A² each independently represent a nitrogen atom or a carbon atom, Ar¹ represents a substituted or unsubstituted aryl group having nucleus carbon atoms of 6 to 60 or a substituted or unsubstituted heteroaryl group having nucleus carbon atoms of 3 to 60, Ar² represents a hydrogen atom, a substituted or unsubstituted aryl group having nucleus carbon atoms of 6 to 60, a substituted or unsubstituted heteroaryl group having nucleus carbon atoms of 3 to 60, a substituted or unsubstituted alkyl group having 1 to 20 carbon atoms or a substituted or unsubstituted alkoxy group having 1 to 20 carbon atoms, wherein one of Ar¹ and Ar² is a substituted or unsubstituted condensed ring group having 10 to 60 nucleus carbon atoms or a substituted or unsubstituted monohetero condensed ring group having 3 to 60 nucleus carbon atoms; L¹ and L² each independently represent a single bond, a substituted or unsubstituted arylene group having 6 to 60 nucleus carbon atoms, a substituted or unsubstituted heteroarylene group having 3 to 60 nucleus carbon atoms or a substituted or unsubstituted fluorenylene group; and R′ and R″ each independently represent a hydrogen atom, a substituted or unsubstituted aryl group having 6 to 60 nucleus carbon atoms, a substituted or unsubstituted heteroaryl group having 3 to 60 nucleus carbon atoms, a substituted or unsubstituted alkyl group having 1 to 20 carbon atoms or a substituted or unsubstituted alkoxy group having 1 to 20 carbon atoms, R′ and R″ may be different from or identical to each other.

<4> The organic electroluminescence element according to any one of <1> to <3>, wherein in the nitrogen-containing heterocyclic derivative represented by any one of General Formulae (1), (3) and (4), at least one of L¹ and L² is selected from groups each independently represented by Structural Formulae below:

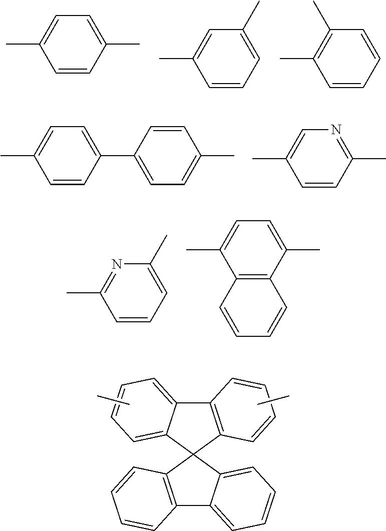

<5> The organic electroluminescence element according to any one of <1> to <4>, wherein in the nitrogen-containing heterocyclic derivative represented by any one of General Formulae (1), (3) and (4), Ar¹ is a group represented by any one of General Formulae (5) to (14) below:

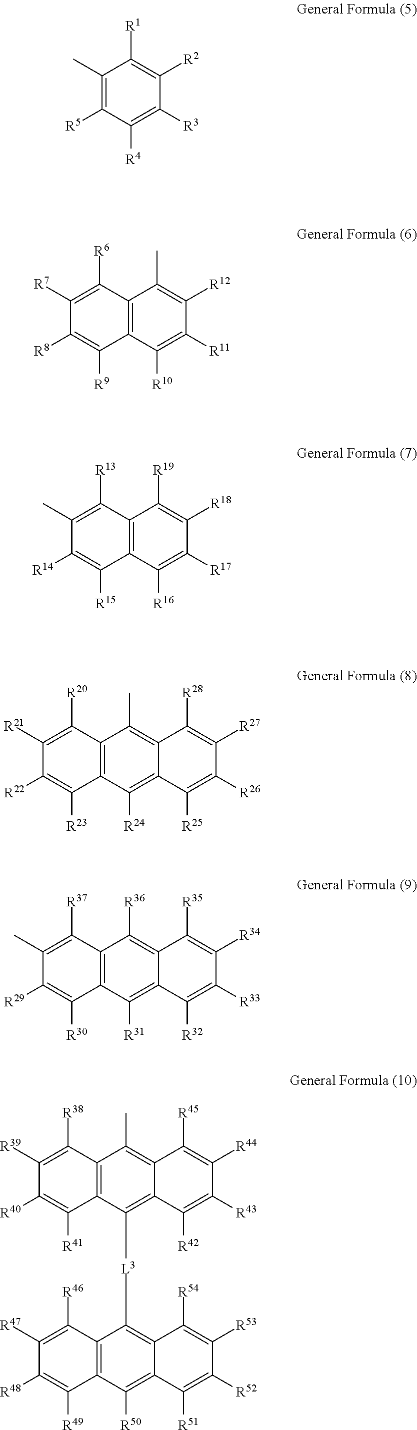

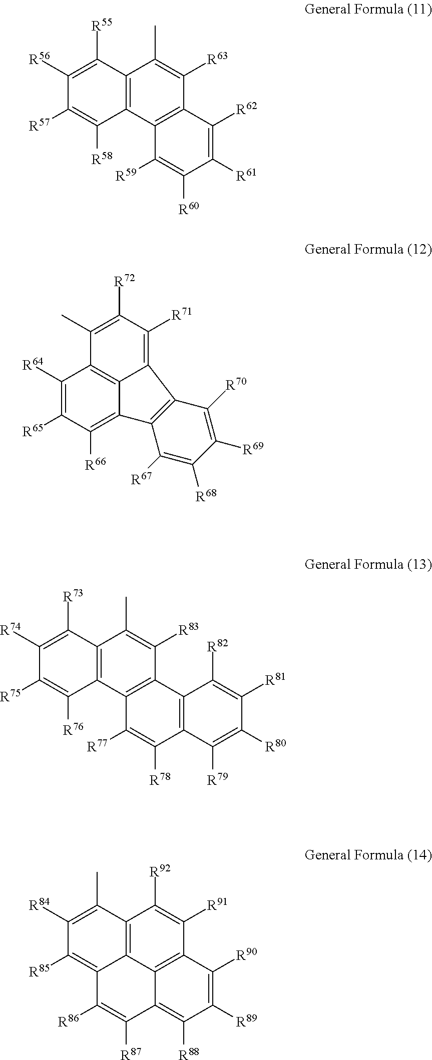

where R¹ to R⁹² each independently represent a hydrogen atom, a halogen atom, a substituted or unsubstituted alkyl group having 1 to 20 carbon atoms, a substituted or unsubstituted alkoxy group having 1 to 20 carbon atoms, a substituted or unsubstituted aryloxy group having 6 to 40 nucleus carbon atoms, a substituted or unsubstituted diarylamino group having 12 to 80 nucleus carbon atoms, a substituted or unsubstituted aryl group having 6 to 40 nucleus carbon atoms, a substituted or unsubstituted heteroaryl group having 3 to 40 nucleus carbon atoms, or a substituted or unsubstituted diarylaminoaryl group having 18 to 120 nucleus carbon atoms; and L³ represents a single bond or a substituent represented by any one of Structural Formulae below:

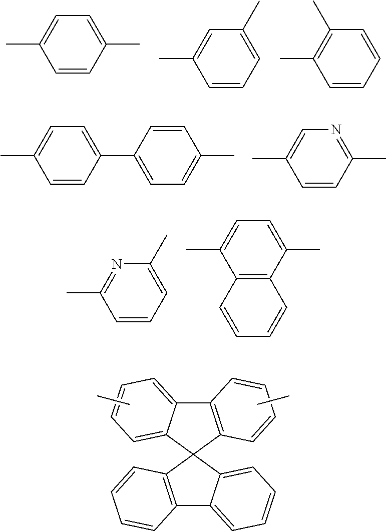

<6> The organic electroluminescence element according to any one of <1> to <5>, wherein the compound represented by General Formula (2) is a compound represented by General Formula 15:

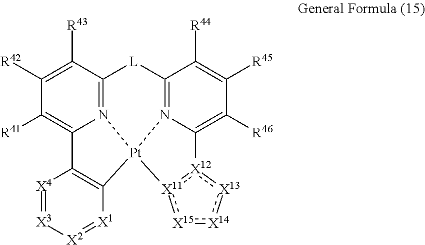

In General Formula (15), X¹, X², X³ and X⁴ each independently represent a carbon atom or a nitrogen atom and one or more selected from X¹, X², X³ and X⁴ represents or represent a nitrogen atom; R⁴¹, R⁴², R⁴³, R⁴⁴, R⁴⁵ and R⁴⁶ each independently represent a hydrogen atom or a substituent; X¹¹ and X¹² each independently represent a carbon atom or a nitrogen atom; X¹³, X¹⁴ and X¹⁵ each independently represent a carbon atom, a nitrogen atom or a sulfur atom, the number of nitrogen atoms contained in a five-membered ring skeleton represented by any one of X¹¹, X¹², X¹³, X¹⁴ and R¹⁵ is 2 or smaller; and L represents a single bond or a divalent linking group.

<7> The organic electroluminescence element according to <6>, wherein the compound represented by General Formula (15) is a compound represented by General formula (15a-1) below:

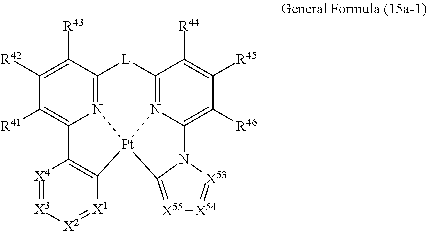

where X¹, X², X³ and X⁴ each independently represent a carbon atom or a nitrogen atom, one or more selected from X¹, X², X³ and X⁴ represents a nitrogen atom; R⁴¹, R⁴², R⁴³, R⁴⁴, R⁴⁵ and R⁴⁶ each independently represent a hydrogen atom or a substituent; X⁵³, X⁵⁴ and X⁵⁵ each independently represent a carbon atom or a nitrogen atom, and the number of nitrogen atoms contained in a five-membered ring skeleton containing X⁵³, X⁵⁴ and X⁵⁵ is 1 or 2; and L represents a single bond or a divalent linking group.

<8> The organic electroluminescence element according to <7>, wherein the compound represented by General Formula (15a-1) is a compound represented by General Formula (15a-2) below:

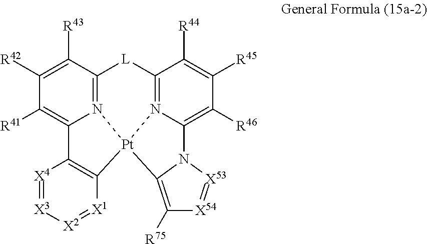

where X¹, X², X³ and X⁴ each independently represent a carbon atom or a nitrogen atom, one or more selected from X¹, X², X³ and X⁴ represents a nitrogen atom; R⁴¹, R⁴², R⁴³, R⁴⁴, R⁴⁵ and R⁴⁶ each independently represent a hydrogen atom or a substituent; X⁵³ and X⁵⁴ each independently represent a carbon atom or a nitrogen atom, and the number of nitrogen atoms contained in a five-membered ring skeleton containing X⁵³ and X⁵⁴ is 1 or 2; R⁷⁵ represents a hydrogen atom or a substituent; and L represents a single bond or a divalent linking group.

<9> The organic electroluminescence element according to <8>, wherein the compound represented by General Formula (15a-2) is a compound represented by General Formula (15a-3):

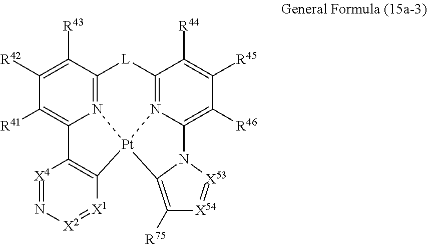

where X¹, X² and X⁴ each independently represent a carbon atom or a nitrogen atom; R⁴¹, R⁴², R⁴³, R⁴⁴, R⁴⁵ and R⁴⁶ each independently represent a hydrogen atom or a substituent; X⁵³ and X⁵⁴ each independently represent a carbon atom or a nitrogen atom, the number of nitrogen atoms contained in a 5-membered ring skeleton containing X⁵³ and X⁵⁴ is 1 or 2; R⁷⁵ represents a hydrogen atom or a substituent; and L represents a single bond or a divalent linking group.

<10> The organic electroluminescence element according to <6>, wherein the compound represented by General Formula (15) is a compound represented by General Formula (15b-1):

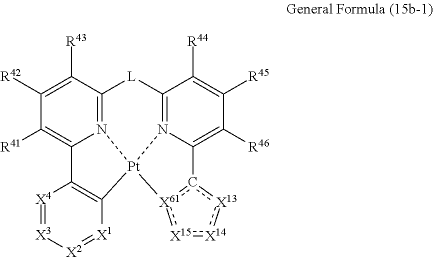

where X¹, X², X³ and X⁴ each independently represent a carbon atom or a nitrogen atom, one or more selected from X¹, X², X³ and X⁴ represents a nitrogen atom; R⁴¹, R⁴², R⁴³, R⁴⁴, R⁴⁵ and R⁴⁶ each independently represents a hydrogen atom or a substituent; X⁶¹ represents a carbon atom or a nitrogen atom; X¹³, X¹⁴ and X¹⁵ each independently represent a carbon atom, a nitrogen atom, an oxygen atom or a sulfur atom; the number of nitrogen atoms contained in a five-membered ring skeleton containing X⁶¹, a carbon atom, X¹³, X¹⁴ and X¹⁵ is 2 or less; and L represents a single bond or a divalent linking group.

<11> The organic electroluminescence element according to <10>, wherein the compound represented by General Formula (15b-1) is a compound represented to by General Formula (15b-2):

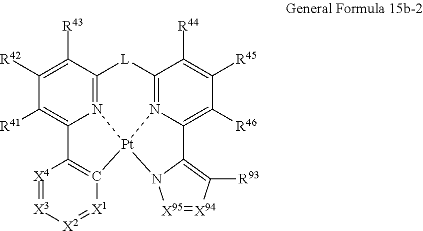

where X¹, X², X³ and X⁴ each independently represent a carbon atom or a nitrogen atom, one or more selected from X¹, X², X³ and X⁴ represents a nitrogen atom; R⁴¹, R⁴², R⁴³, R⁴⁴, R⁴⁵ and R⁴⁶ each independently represent a hydrogen atom or a substituent; X⁹⁴ and X⁹⁵ each independently represent a carbon atom or a nitrogen atom, and at least one of X⁹⁴ and X⁹⁵ represents a carbon atom; R⁹³ represents a hydrogen atom or a substituent; and L represents a single bond or a divalent linking group.

<12> The organic electroluminescence element according to <11>, wherein the compound represented by General Formula (15b-2) is a compound represented by General Formula (15b-3):

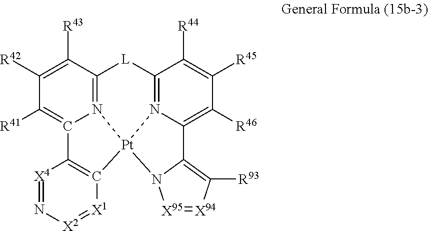

where X¹, X² and X⁴ each independently represent a carbon atom or a nitrogen atom, one or more selected from X¹, X² and X⁴ represents a nitrogen atom; R⁴¹, R⁴², R⁴³, R⁴⁴, R⁴⁵ and R⁴⁶ each independently represent a hydrogen atom or a substituent; X⁹⁴ and X⁹⁵ each independently represent a carbon atom or a nitrogen atom; at least one of X⁹⁴ and X⁹⁵ represents a carbon atom; R⁹³ represents a hydrogen atom or a substituent; and L represents a single bond or a divalent linking group.

<13> The organic electroluminescence element according to any one of <1> to <12>, wherein the light emitting layer contains a metal complex compound containing a polydentate ligand having a partial structure represented by General Formula (2), and at least one of platinum complex compounds containing a tetradentate ligand represented by any one of General Formulae (15), (15a-1), (15a-2), (15a-3), (15b-1), (15b-2), and (15b-3).

<14> The organic electroluminescence element according to any one of <1> to <13>, wherein the light emitting layer contains a metal complex compound containing a polydentate ligand having a partial structure represented by General Formula (2), at least one of platinum complex compounds containing a tetradentate ligand represented by any one of General Formulae (15), (15a-1), (15a-2), (15a-3), (15b-1), (15b-2), and (15b-3), and at least one host material.

<15> The organic electroluminescence element according to <14>, wherein the at least one host material is hole transportable.

<16> The organic electroluminescence element according to any one of <1> to <15>, wherein the nitrogen-containing heterocyclic derivative functions as at least one of an electron injection material and an electron transporting material.

<17> The organic electroluminescence element according to any one of <1> to <16>, wherein the layer containing the nitrogen-containing heterocyclic derivative contains a reducing dopant.

<18> The organic electroluminescence element according to <17>, wherein the reducing dopant is at least one selected from alkali metals, alkaline earth metals, rare earth metals, alkali metal oxides, alkali metal halides, alkali earth metal oxides, alkali earth metal halides, rare earth metal oxides, rare earth metal halides, alkali metal organic complexes, alkali earth metal organic complexes, and rare earth metal organic complexes.

The present invention can solve conventional problems and provide an organic electroluminescence element capable of reducing driving voltage and maintaining high light emission efficiency.

### BRIEF DESCRIPTION OF DRAWINGS

FIG. 1 is a schematic diagram illustrating one example of a layer configuration of an organic electroluminescence element according to the present invention.

### DESCRIPTION OF EMBODIMENTS

### Organic Electroluminescence Element

The organic electroluminescence element of the present invention includes at least one organic layer including a light emitting layer, between an anode and a cathode, wherein at least one layer of the at least one organic layer contains at least one selected from specific nitrogen-containing heterocyclic derivatives, and at least one layer of the at least one organic layer contains an electron-transporting phosphorous light emitting material.

### <Nitrogen-Containing Heterocyclic Derivative>

The nitrogen-containing heterocyclic derivative contains at least one selected from nitrogen-containing heterocyclic derivatives represented by General Formula (1);

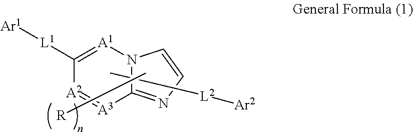

where A¹ to A³ each independently represent a nitrogen atom or a carbon atom, Ar¹ represents a substituted or unsubstituted aryl group having nucleus carbon atoms of 6 to 60 or a substituted or unsubstituted heteroaryl group having nucleus carbon atoms of 3 to 60, Ar² represents a hydrogen atom, a substituted or unsubstituted aryl group having nucleus carbon atoms of 6 to 60, a substituted or unsubstituted heteroaryl group having nucleus carbon atoms of 3 to 60, a substituted or unsubstituted alkyl group having 1 to 20 carbon atoms or a substituted or unsubstituted alkoxy group having 1 to 20 carbon atoms, wherein one of Ar¹ and Ar² is a substituted or unsubstituted condensed ring group having 10 to 60 nucleus carbon atoms or a substituted or unsubstituted monohetero condensed ring group having 3 to 60 nucleus carbon atoms; L¹ and L² each independently represent a single bond, a substituted or unsubstituted arylene group having 6 to 60 nucleus carbon atoms, a substituted or unsubstituted heteroarylene group having 3 to 60 nucleus carbon atoms or a substituted or unsubstituted fluorenylene group; R represents a hydrogen atoms, a substituted or unsubstituted aryl group having 6 to 60 nucleus carbon atoms, a substituted or unsubstituted heteroaryl group having nucleus carbon atoms of 3 to 60, a substituted or unsubstituted alkyl group having 1 to 20 carbon atoms or a substituted or unsubstituted alkoxy group having 1 to 20 carbon atoms; and n is an integer of 0 to 5, when n is 2 or greater, a plurality of Rs may be different from or identical to each other, and adjacent R groups among the plurality of Rs may be bonded to form a carbocyclic aliphatic ring or a carbocyclic aromatic ring.

The nitrogen-containing heterocyclic derivative represented by General Formula (1) is preferably a nitrogen-containing heterocyclic derivative represented by General Formula (3) below.

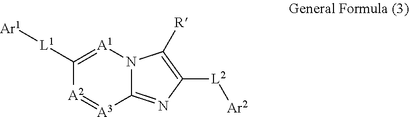

where A¹ to A³ each independently represent a nitrogen atom or a carbon atom, Ar¹ represents a substituted or unsubstituted aryl group having nucleus carbon atoms of 6 to 60 or a substituted or unsubstituted heteroaryl group having nucleus carbon atoms of 3 to 60, Ar² represents a hydrogen atom, a substituted or unsubstituted aryl group having nucleus carbon atoms of 6 to 60, a substituted or unsubstituted heteroaryl group having nucleus carbon atoms of 3 to 60, a substituted or unsubstituted alkyl group having 1 to 20 carbon atoms or a substituted or unsubstituted alkoxy group having 1 to 20 carbon atoms, wherein one of Ar¹ and Ar² is a substituted or unsubstituted condensed ring group having nucleus carbon atoms of 10 to 60 or a substituted or unsubstituted monohetero condensed ring group having nucleus carbon atoms of 3 to 60; L¹ and L² each independently represent a single bond, a substituted or unsubstituted arylene group having 6 to 60 nucleus carbon atoms, a substituted or unsubstituted heteroarylene group having 3 to 60 nucleus carbon atoms or a substituted or unsubstituted fluorenylene group; and R′ represents a hydrogen atom, a substituted or unsubstituted aryl group having 6 to 60 nucleus carbon atoms, a substituted or unsubstituted heteroaryl group having 3 to 60 nucleus carbon atoms, a substituted or unsubstituted alkyl group having 1 to 20 carbon atoms or a substituted or unsubstituted alkoxy group having 1 to 20 carbon atoms.

The nitrogen-containing heterocyclic derivative represented by General Formula (3) is preferably a nitrogen-containing heterocyclic derivative represented by General Formula (4) below.

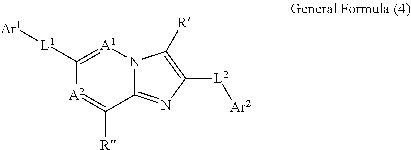

where A¹ and A² each independently represent a nitrogen atom or a carbon atom, Ar¹ represents a substituted or unsubstituted aryl group having nucleus carbon atoms of 6 to 60 or a substituted or unsubstituted heteroaryl group having nucleus carbon atoms of 3 to 60, Ar² represents a hydrogen atom, a substituted or unsubstituted aryl group having nucleus carbon atoms of 6 to 60, a substituted or unsubstituted heteroaryl group having nucleus carbon atoms of 3 to 60, a substituted or unsubstituted alkyl group having 1 to 20 carbon atoms or a substituted or unsubstituted alkoxy group having 1 to 20 carbon atoms, wherein one of Ar¹ and Ar² is a substituted or unsubstituted condensed ring group having 10 to 60 nucleus carbon atoms or a substituted or unsubstituted monohetero condensed ring group having 3 to 60 nucleus carbon atoms.

L¹ and L² each independently represent a single bond, a substituted or unsubstituted arylene group having 6 to 60 nucleus carbon atoms, a substituted or unsubstituted heteroarylene group having 3 to 60 nucleus carbon atoms or a substituted or unsubstituted fluorenylene group.

R′ and R″ each independently represent a hydrogen atom, a substituted or unsubstituted aryl group having 6 to 60 nucleus carbon atoms, a substituted or unsubstituted heteroaryl group having 3 to 60 nucleus carbon atoms, a substituted or unsubstituted alkyl group having 1 to 20 carbon atoms or a substituted or unsubstituted alkoxy group having 1 to 20 carbon atoms, and R′ and R″ may be different from or identical to each other.

In the nitrogen-containing heterocyclic derivative represented by any one of General Formulae (1), (3) and (4), at least one of L¹ and L² is selected from groups each independently represented by Structural Formulae below.

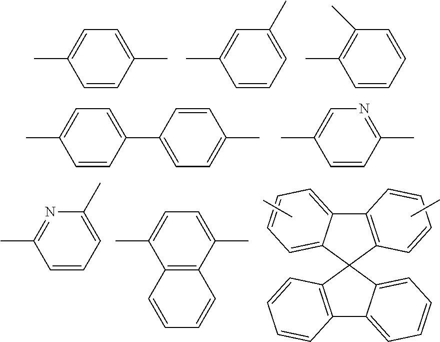

In the nitrogen-containing heterocyclic derivative represented by any one of General Formulae (1), (3) and (4), Ar¹ is a group represented by any one of General Formulae (5) to (14) below:

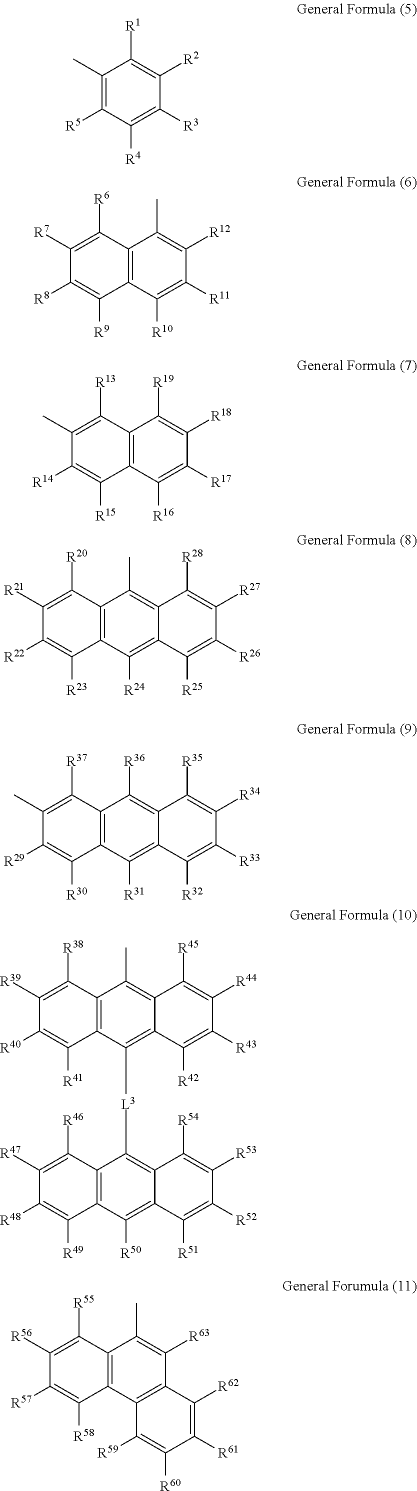

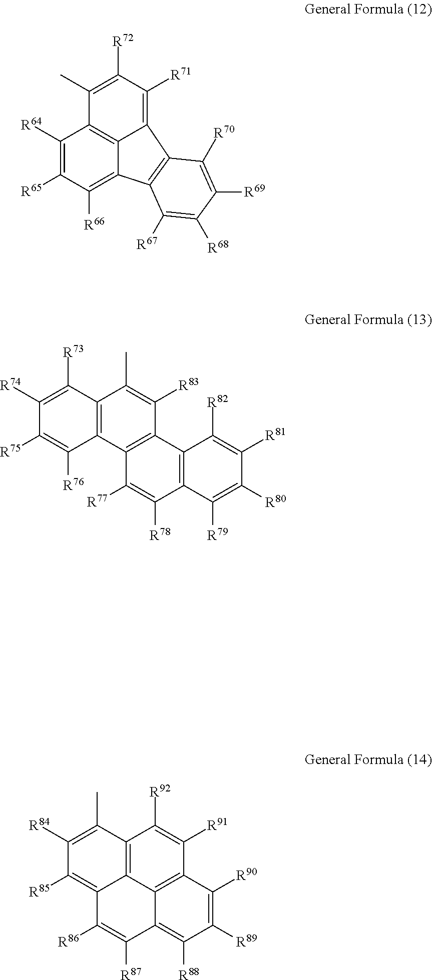

where R¹ to R⁹² each independently represent a hydrogen atom, a halogen atom, a substituted or unsubstituted alkyl group having 1 to 20 carbon atoms, a substituted or unsubstituted alkoxy group having 1 to 20 carbon atoms, a substituted or unsubstituted aryloxy group having 6 to 40 nucleus carbon atoms, a substituted or unsubstituted diarylamino group having 12 to 80 nucleus carbon atoms, a substituted or unsubstituted aryl group having 6 to 40 nucleus carbon atoms, a substituted or unsubstituted heteroaryl group having 3 to 40 nucleus carbon atoms, or a substituted or unsubstituted diarylaminoaryl group having 18 to 120 nucleus carbon atoms; and L³ represents a single bond or a substituent represented by any one of Structural Formulae below:

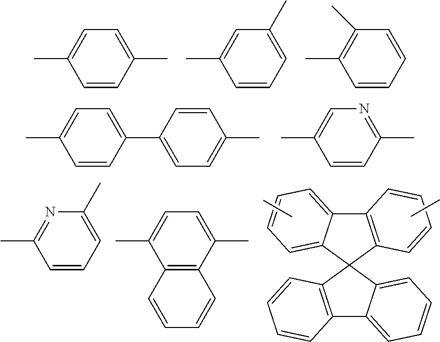

Specific examples of the nitrogen-containing heterocyclic derivative that can be used in the present invention include the following compounds, but not limited thereto.

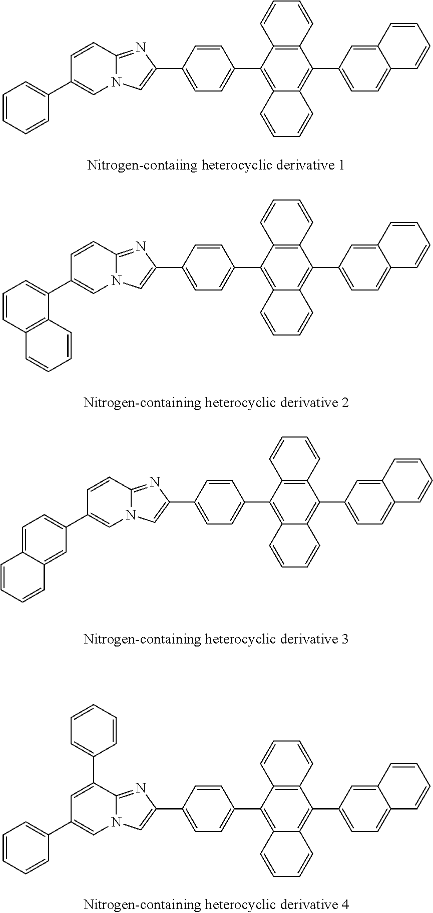

The nitrogen-containing heterocyclic derivative is preferably used as at least one of an electron injection material and an electron transporting material.

The nitrogen-containing heterocyclic derivative is contained in at least one organic layer, which is preferably at least one of an electron injection layer and an electron transporting layer.

The electron injection layer and the electron transporting layer are layers having a function to receive electrons from a cathode or cathode side and transport the electrons to the anode side.

The layers containing the nitrogen-containing heterocyclic derivative (the organic layer, electron injection layer, and electron transporting layer) preferably contain a reducing dopant.

The reducing dopant is preferably at least one selected from alkali metals, alkaline earth metals, rare earth metals, alkali metal oxides, alkali metal halides, alkali earth metal oxides, alkali earth metal halides, rare earth metal oxides, rare earth metal halides, alkali metal organic complexes, alkali earth metal organic complexes, and rare earth metal organic complexes.

The use amount of the reducing dopant varies depending on the type of the material, and it is, however, preferably 0.1% by mass to 99% by mass, more preferably 0.3% by mass to 80% by mass, and still more preferably 0.5% by mass to 50% by mass relative to the amount of the material for the electron transporting layer or electron injection layer.

The electron transporting layer and the electron injecting layer may be formed according to known methods. For example, these layers can be suitably formed by a vacuum deposition method, wet-process film forming method, MBE (Molecular Beam epitaxy) method, cluster ion beam method, molecule lamination method, LB method, printing method, transfer method and the like.

The thickness of the electron transporting layer preferably is preferably 1 nm to 200 nm, more preferably 1 nm to 100 nm, and still more preferably 1 nm to 50 nm.

The thickness of the electron injecting layer is preferably 1 nm to 200 nm, more preferably 1 nm to 100 nm, and still more preferably 1 nm to 50 nm.

### <Electron-Transporting Phosphorous Light Emitting Material>

The electron-transporting phosphorous light emitting material preferably contains an electron-transporting phosphorous light emitting material represented by the following General Formula (2).

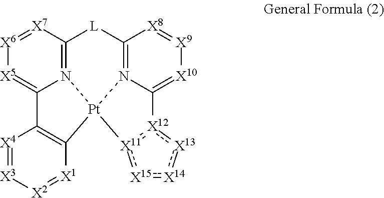

In General Formula (2), X¹, X², X³ and X⁴ each independently represent a carbon atom or a nitrogen atom, and one or more selected from X¹, X², X³ and X⁴ represents or represent a nitrogen atom; X⁵, X⁶, X⁷, X⁸, X⁹ and X¹⁰ each independently represent a carbon atom or a nitrogen atom; X¹¹ and X¹² each independently represent a carbon atom or a nitrogen atom; X¹³, X¹⁴ and X¹⁵ each independently represent a carbon atom, a nitrogen atom, an oxygen atom or a sulfur atom, the number of nitrogen atoms contained in a five-membered ring skeleton represented by any one of X¹¹, X¹², X¹³, X¹⁴ and X¹⁵ is 2 or smaller; and L represents a single bond or a divalent linking group.

The compound represented by General Formula (2) is preferably a compound represented by General Formula (15) below.

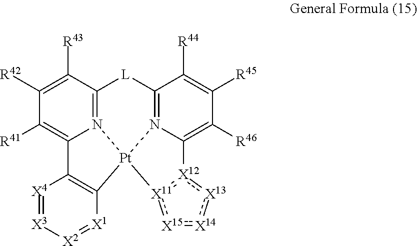

In General Formula (15), X¹, X², X³ and X⁴ each independently represent a carbon atom or a nitrogen atom and one or more selected from X¹, X², X³ and X⁴ represents or represent a nitrogen atom; R⁴¹, R⁴², R⁴³, R⁴⁴, R⁴⁵ and R⁴⁶ each independently represent a hydrogen atom or a substituent; X¹¹ and X¹² each independently represent a carbon atom or a nitrogen atom;, X¹³, X¹⁴ and X¹⁵ each independently represent a carbon atom, a nitrogen atom or a sulfur atom, the number of nitrogen atoms contained in a five-membered ring skeleton represented by any one of X¹¹, X¹², X¹³, X¹⁴ and X¹⁵ is 2 or smaller; and L represents a single bond or a divalent linking group.

The compound represented by General Formula (15) is preferably a compound represented by General formula (15a-1) below:

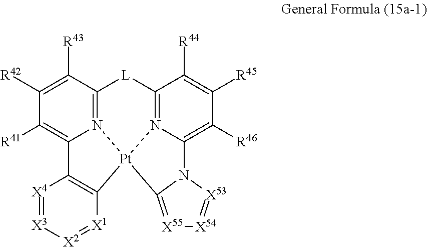

where X¹, X², X³ and X⁴ each independently represent a carbon atom or a nitrogen atom, one or more selected from X¹, X², X³ and X⁴ represents a nitrogen atom; R⁴¹, R⁴², R⁴³, R⁴⁴, H⁴⁵ and R⁴⁶ each independently represent a hydrogen atom or a substituent; X⁵³, X⁵⁴ and X⁵⁵ each independently represent a carbon atom or a nitrogen atom, and the number of nitrogen atoms contained in a five-membered ring skeleton containing X⁵³, X⁵⁴ and X⁵⁵ is 1 or 2; and L represents a single bond or a divalent linking group.

The compound represented by General Formula (15a-1) is preferably a compound represented by General Formula (15a-2) below.

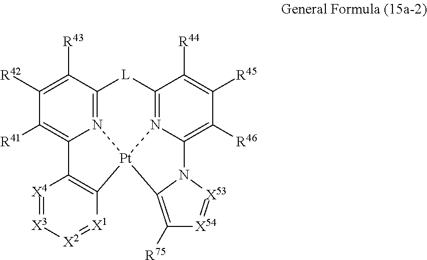

In General Formula (15a-2), X¹, X², X³ and X⁴ each independently represent a carbon atom or a nitrogen atom, one or more selected from X¹, X², X³ and X⁴ represents a nitrogen atom; R⁴¹, R⁴², R⁴³, R⁴⁴, R⁴⁵ and R⁴⁶ each independently represent a hydrogen atom or a substituent; X⁵³ and X⁵⁴ each independently represent a carbon atom or a nitrogen atom, and the number of nitrogen atoms contained in a five-membered ring skeleton containing X⁵³ and X⁵⁴ is 1 or 2; R⁷⁵ represents a hydrogen atom or a substituent; and L represents a single bond or a divalent linking group.

The compound represented by General Formula (15a-2) is preferably a compound represented by General Formula (15a-3) below.

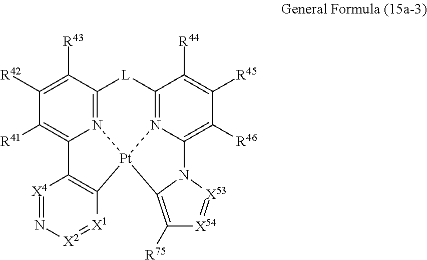

In General Formula (15a-3), X¹, X² and X⁴ each independently represent a carbon atom or a nitrogen atom; R⁴¹, R⁴², R⁴³, R⁴⁴, R⁴⁵ and R⁴⁶ each independently represent a hydrogen atom or a substituent; X⁵³ and X⁵⁴ each independently represent a carbon atom or a nitrogen atom, the number of nitrogen atoms contained in a 5-membered ring skeleton containing X⁵³ and X⁵⁴ is 1 or 2; R⁷⁵ represents a hydrogen atom or a substituent; and L represents a single bond or a divalent linking group.

The compound represented by General Formula (15) is preferably a compound represented by General Formula (15b-1) below.

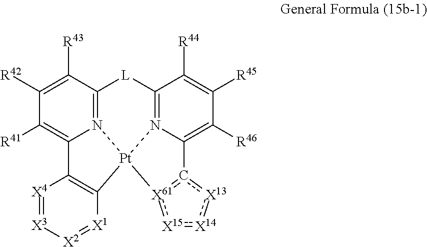

In General Formula (15b-1), X¹, X², X³ and X⁴ each independently represent a carbon atom or a nitrogen atom, one or more selected from X¹, X², X³ and X⁴ represents a nitrogen atom; R⁴¹, R⁴², R⁴³, R⁴⁴, R⁴⁵ and R⁴⁶ each independently represents a hydrogen atom or a substituent; X⁶¹ represents a carbon atom or a nitrogen atom; X¹³, X¹⁴ and X¹⁵ each independently represent a carbon atom, a nitrogen atom, an oxygen atom or a sulfur atom; the number of nitrogen atoms contained in a five-membered ring skeleton containing X⁶¹, a carbon atom, X¹³, X¹⁴ and X¹⁵ is 2 or less; and L represents a single bond or a divalent linking group.

The compound represented by General Formula (15b-1) is preferably a compound represented by General Formula (15b-2) below.

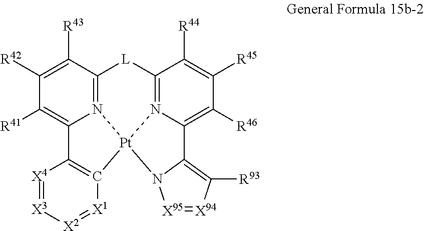

In General Formula (15b-2), X¹, X², X³ and X⁴ each independently represent a carbon atom or a nitrogen atom, one or more selected from X¹, X², X³ and X⁴ represents a nitrogen atom; R⁴¹, R⁴², R⁴³, R⁴⁴, R⁴⁵ and R⁴⁶ each independently represent a hydrogen atom or a substituent; X⁹⁴ and X⁹⁵ each independently represent a carbon atom or a nitrogen atom, and at least one of X⁹⁴ and X⁹⁵ represents a carbon atom; R⁹³ represents a hydrogen atom or a substituent; and L represents a single bond or a divalent linking group.

The compound represented by General Formula (15b-2) is preferably a compound represented by General Formula (15b-3) below.

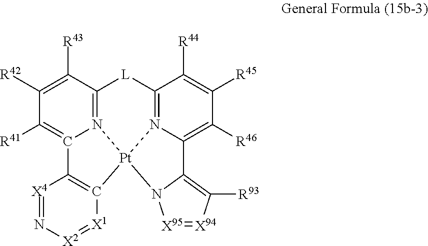

General Formula (15b-3), X¹, X² and X⁴ each independently represent a carbon atom or a nitrogen atom, one or more selected from X¹, X² and X⁴ represents a nitrogen atom; R⁴¹, R⁴², R⁴³, R⁴⁴, R⁴⁵ and R⁴⁶ each independently represent a hydrogen atom or a substituent; X⁹⁴ and X⁹⁵ each independently represent a carbon atom or a nitrogen atom; at least one of X⁹⁴ and X⁹⁵ represents a carbon atom; R⁹³ represents a hydrogen atom or a substituent; and L represents a single bond or a divalent linking group.

Specific examples of the electron-transporting phosphorous light emitting material usable in the present invention include the following compounds, but not limited thereto.

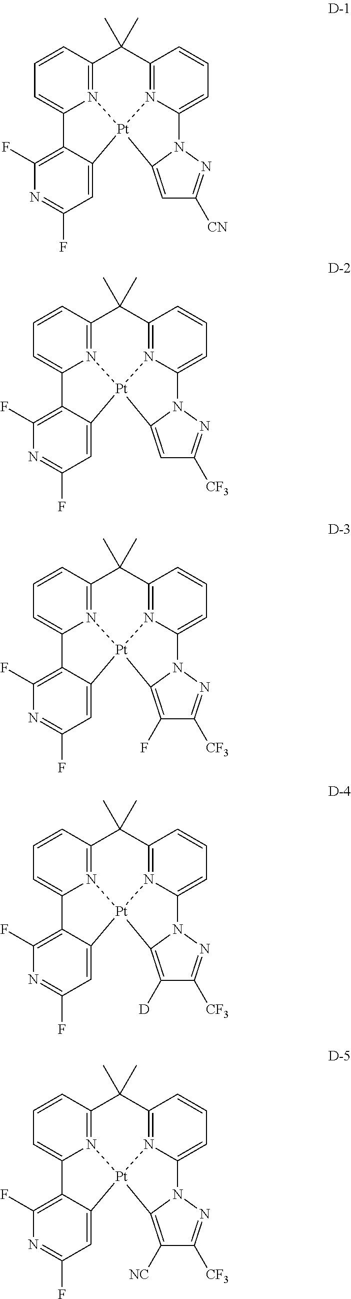

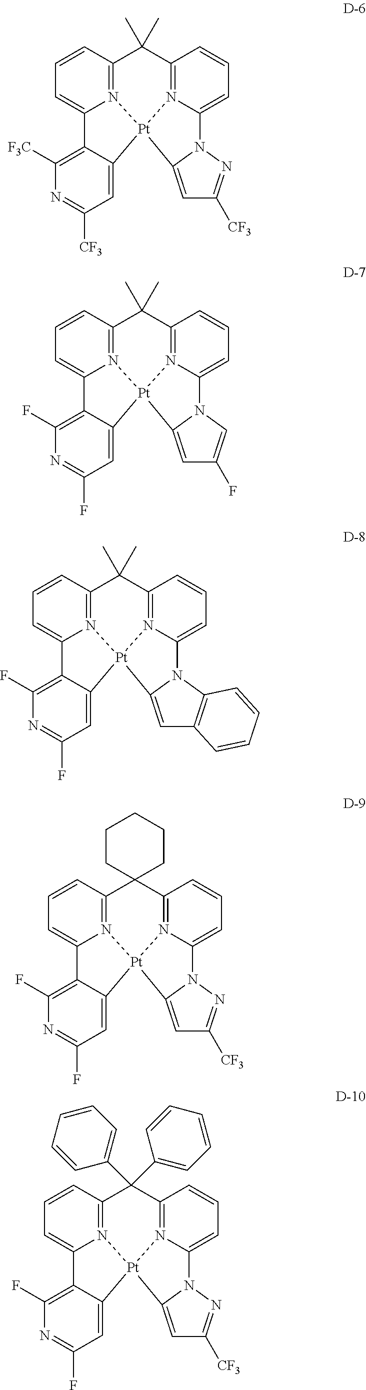

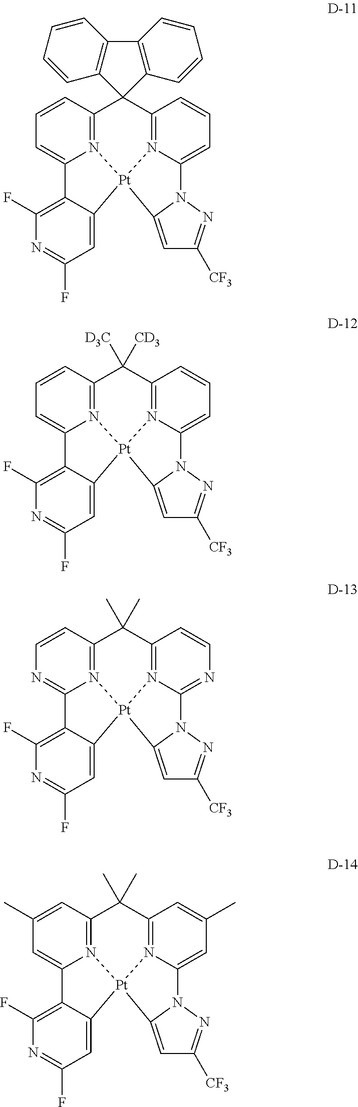

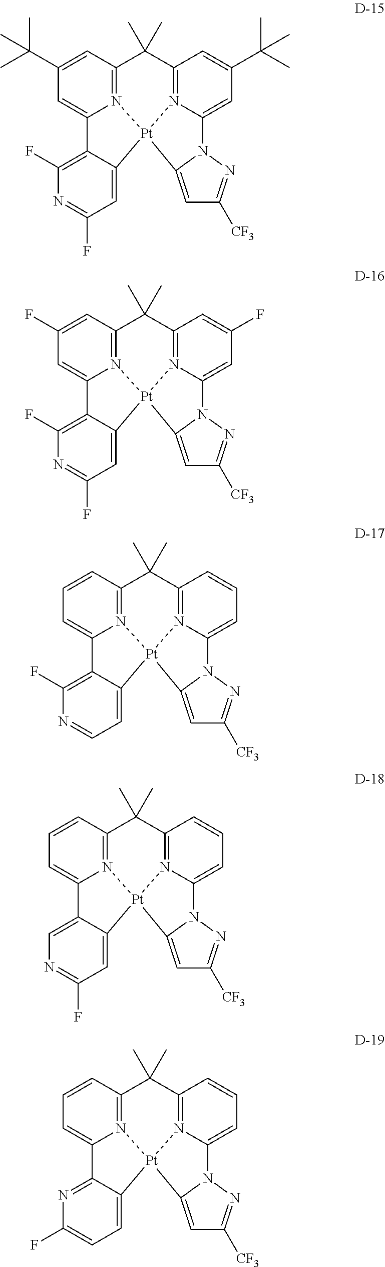

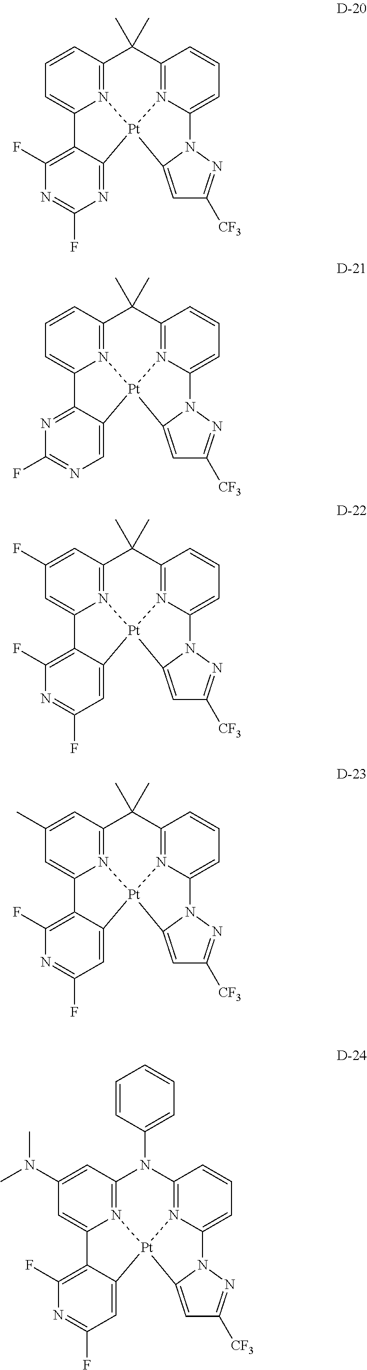

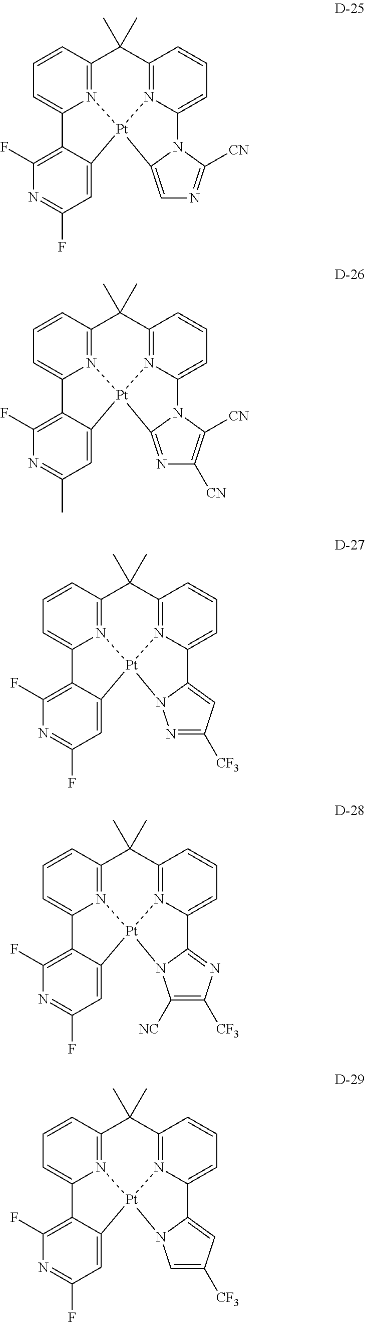

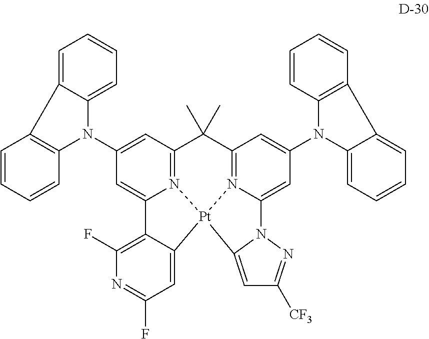

The metal complex compound containing a polydentate ligand having a partial structure represented by General Formula (2), and at least one of platinum complex compounds containing a tetradentate ligand represented by any one of General Formulae (15), (15a-1), (15a-2), (15a-3), (15b-1), (15b-2), and (15b-3) are contained in at least one layer of the organic layers, and preferably contained in the light emitting layer.

The metal complex compound containing a polydentate ligand having a partial structure represented by General Formula (2), at least one of platinum complex compounds containing a tetradentate ligand represented by any one of General Formulae (15), (15a-1), (15a-2), (15a-3), (15b-1), (15b-2), and (15b-3), and at least one host material are preferably contained in the light emitting layer, and additives such as adamantine may be contained therein.

In this case, the amount of the electron-transporting phosphorous light emitting material serving as the light emitting dopant is preferably 0.1% by mass to 90% by mass, more preferably 1% by mass to 50% by mass, and still more preferably 1% by mass to 25% by mass.

As the host material, both an electron transporting host and a hole-transporting host are preferably used, and these hosts may be used in combination.

### <Electron Transporting Host Material>

The electron transporting host material used in the present invention preferably has an electron affinity Ea, from the viewpoint of improvement of durability and reduction in driving voltage, of 2.5 eV to 3.5 eV, more preferably 2.6 eV to 3.4 eV, particularly preferably 2.8 eV to 3.3 eV, and preferably has an ionization potential Ip, from the viewpoint of improvement of durability and reduction in driving voltage, of 5.7 eV to 7.5 eV, more preferably 5.8 eV to 7.0 eV, particularly preferably 5.9 eV to 6.5 eV.

The lowest triplet excitation energy value (hereinbelow, referred to as T1) of the electron transporting host material is preferably 2.2 eV to 3.7 eV, more preferably 2.4 eV to 3.7 eV, and most preferably 2.4 eV to 3.4 eV.

Specific examples of such electron transporting hosts include pyridine, pyrimidine, triazine, imidazole, pyrazole, triazole, oxazole, oxadiazole, fluorenone, anthraquinodimethane, anthrone, diphenylquinone, thiopyrandioxide, carbodiimide, fluorenylidenemethane, distyrylpyrazine, fluorine-substituted aromatic compounds, heterocyclic tetracarboxylic anhydrides of naphthalene, perylene or the like, phthalocyanine, derivatives thereof (which may form a condensed ring with another ring), and a variety of metal complexes typified by metal complexes of 8-quinolinol derivatives, metal phthalocyanine, and metal complexes having benzoxazole or benzothiazole as the ligand.

Preferred examples of the electron transporting hosts are metal complexes, azole derivatives (benzimidazole derivatives, imidazopyridine derivatives etc.), and azine derivatives (pyridine derivatives, pyrimidine derivatives, triazine derivatives etc.). Among these, more preferred are metal complex compounds, from the viewpoint of durability. As the metal complex compound, a metal complex containing a ligand having at least one nitrogen atom, oxygen atom, or sulfur atom to be coordinated with the metal is more preferable.

Although a metal ion in the metal complex is not particularly limited, a beryllium ion, a magnesium ion, an aluminum ion, a gallium ion, a zinc ion, an indium ion, a tin ion, a platinum ion, or a palladium ion is preferred; more preferred is a beryllium ion, an aluminum ion, a gallium ion, a zinc ion, a platinum ion, or a palladium ion; and further preferred is an aluminum ion, a zinc ion, a platinum ion or a palladium ion.

Although there are a variety of well-known ligands to be contained in the above-described metal complexes, examples thereof include ligands described in “Photochemistry and Photophysics of Coordination Compounds” authored by H. Yersin, published by Springer-Verlag Co. in 1987; “YUHKI KINZOKU KAGAKU—KISO TO OUYOU (Organometallic Chemistry—Fundamental and Application—)” authored by Akio Yamamoto, published by Shokabo Publishing Co., Ltd. in 1982; and the like.

As the ligands, preferred are nitrogen-containing heterocyclic ligands (preferably having 1 to 30 carbon atoms, more preferably having 2 to 20 carbon atoms, particularly preferably having 3 to 15 carbon atoms). The ligands may be monodentate ligands or bidentate or higher ligands, but are preferably from bidentate ligands to hexadentate ligands, and mixed ligands of a monodentate ligand with a bidentate to hexadentate ligand are also preferable.

Specific examples of the ligands include azine ligands (e.g. pyridine ligands, bipyridyl ligands, terpyridine ligands, etc.); hydroxyphenylazole ligands (e.g. hydroxyphenylbenzimidazole ligands, hydroxyphenylbenzoxazole ligands, hydroxyphenylimidazole ligands, hydroxyphenylimidazopyridine ligands, etc.); alkoxy ligands (e.g. methoxy, ethoxy, butoxy and 2-ethylhexyloxy ligands, and these ligands preferably have 1 to 30 carbon atoms, more preferably have 1 to 20 carbon atoms, particularly preferably have 1 to 10 carbon atoms); aryloxy ligands (e.g. phenyloxy, 1-naphthyloxy, 2-naphthyloxy, 2,4,6-trimethylphenyloxy, and 4-biphenyloxy ligands, and these ligands preferably have 6 to 30 carbon atoms, more preferably have 6 to 20 carbon atoms, particularly preferably have 6 to 12); heteroaryloxy ligands (e.g. pyridyloxy, pyrazyloxy, pyrimidyloxy, quinolyloxy ligands and the like, and those having preferably 1 to 30 carbon atoms, more preferably 1 to 20 carbon atoms, and particularly preferably 1 to 12 carbon atoms); alkylthio ligands (e.g. methylthio, ethylthio ligands and the like, and those having preferably 1 to 30 carbon atoms, more preferably 1 to 20 carbon atoms, and particularly preferably 1 to 12 carbon atoms); arylthio ligands (e.g. phenylthio ligands and the like, and those having preferably 6 to 30 carbon atoms, more preferably 6 to 20 carbon atoms, and particularly preferably 6 to 12 carbon atoms); heteroarylthio ligands (e.g. pyridylthio, 2-benzimidazolylthio, 2-benzoxazolylthio, 2-benzothiazolylthio ligands and the like, and those having preferably 1 to 30 carbon atoms, more preferably 1 to 20 carbon atoms, and particularly preferably 1 to 12 carbon atoms); siloxy ligands (e.g. a triphenylsiloxy group, a triethoxysiloxy group, a triisopropylsiloxy group and the like, and those having preferably 1 to 30 carbon atoms, more preferably 3 to 25 carbon atoms, and particularly preferably 6 to 20 carbon atoms); aromatic hydrocarbon anion ligands (e.g. a phenyl anion, a naphthyl anion, an anthranyl anion and the like, and those having preferably 6 to 30 carbon atoms, more preferably 6 to 25 carbon atoms, and particularly preferably 6 to 20 carbon atoms); aromatic heterocyclic anion ligands (e.g. a pyrrole anion, a pyrazole anion, a triazole anion, an oxazole anion, a benzoxazole anion, a thiazole anion, a benzothiazole anion, a thiophene anion, a benzothiophene anion and the like, and those having preferably 1 to 30 carbon atoms, more preferably 2 to 25 carbon atoms, and particularly preferably 2 to 20 carbon atoms); and indolenine anion ligands. Among these, nitrogen-containing heterocyclic ligands, aryloxy ligands, heteroaryloxy groups, siloxy ligands are preferable. Nitrogen-containing aromatic heterocyclic ligands, aryloxy ligands, siloxy ligands, aromatic hydrocarbon anion ligands, and aromatic heterocyclic anion ligands are more preferable.

Examples of the metal complex electron transporting hosts include compounds described, for example, in Japanese Patent Application Laid-Open (JP-A) Nos. 2002-235076, 2004-214179, 2004-221062, 2004-221065, 2004-221068, and 2004-327313.

Specific examples of such electron transporting host materials include the following materials, but not limited thereto.

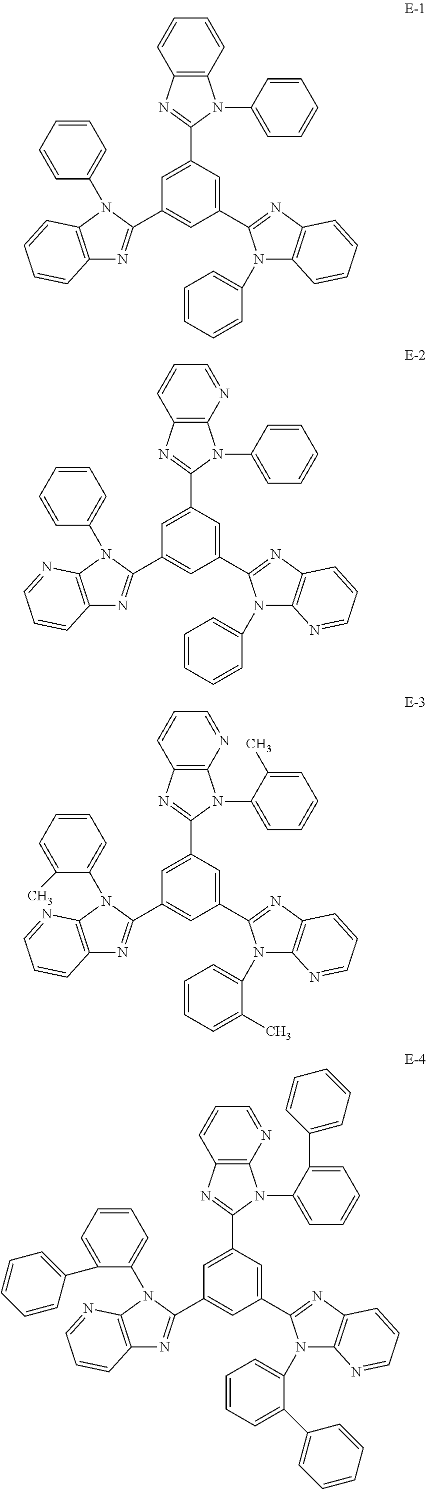

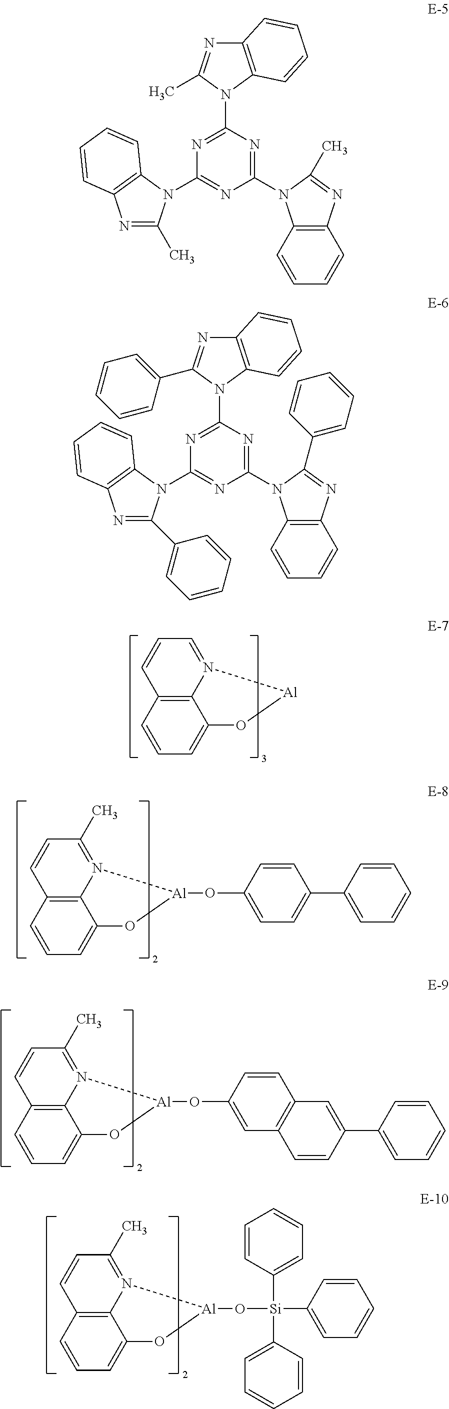

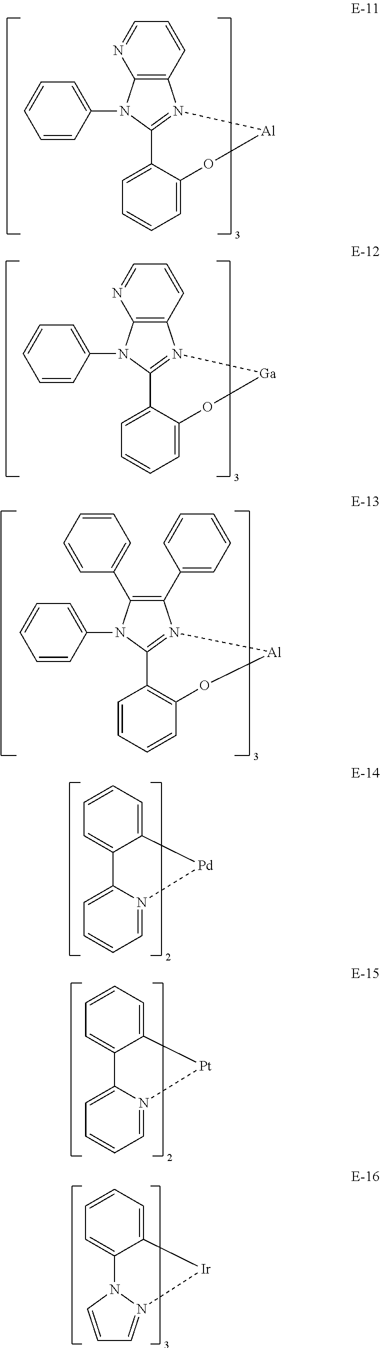

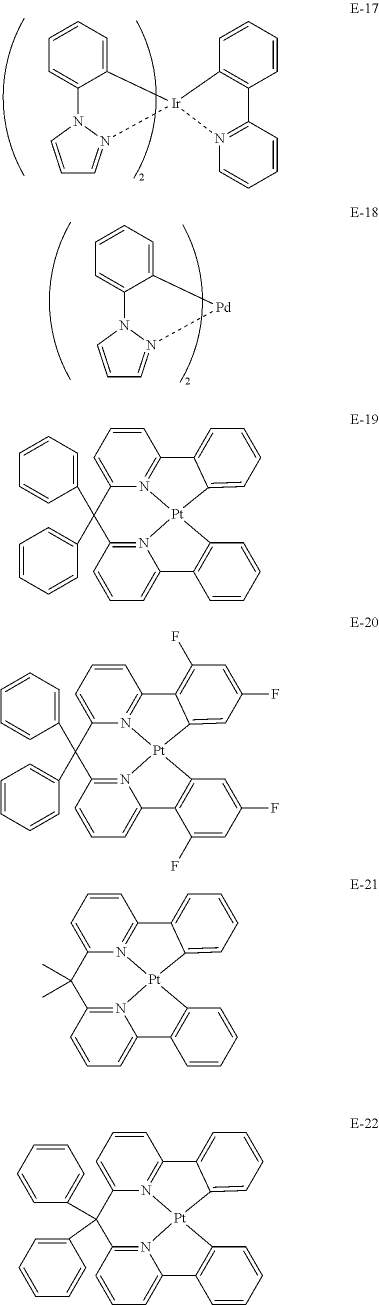

### <Hole Transporting Host Material>

The hole transporting host material used in the light emitting layer of the present invention preferably has an ionization potential Ip, from the viewpoint of improvement of durability and reduction in driving voltage, of 5.1 eV to 6.4 eV, more preferably 5.4 eV to 6.2 eV, and still more preferably 5.6 eV to 6.0 eV. From the viewpoint of improvement of durability and reduction in driving voltage, the electron affinity Ea of the host transporting host material is preferably 1.2 eV to 3.1 eV, more preferably 1.4 eV to 3.0 eV, and still more preferably 1.8 eV to 2.8 eV.

The lowest triplet excitation energy value (hereinbelow, referred to as T1) of the hole transporting host material is preferably 2.2 eV to 3.7 eV, more preferably 2.4 eV to 3.7 eV, and most preferably 2.4 eV to 3.4 eV.

Examples of the hole transporting host material include pyrrole, indole, carbazole, azaindole, azacarbazole, triazole, oxazole, oxadiazole, pyrazole, imidazole, thiophene, polyarylalkane, pyrazoline, pyrazolone, phenylenediamine, arylamine, amino-substituted chalcone, styrylanthracene, fluorenone, hydrazone, stilbene, silazane, aromatic tertiary amine compounds, styrylamine compounds, aromatic dimethylidine compounds, porphyrin compounds, polysilane compounds, poly(N-vinylcarbazole), aniline copolymers, electrically conductive high-molecular oligomers such as thiophene oligomers, polythiophenes and the like, organic silanes, carbon films, derivatives thereof.

Among these, indole derivatives, carbazole derivatives, azaindole derivatives, azacarbazole derivatives, aromatic tertiary amine compounds, and thiophene derivatives are preferred, with compounds each having a plurality of indole skeletons, carbazole skeletons, azaindole skeletons, azacarbazole skeletons or aromatic tertiary amine skeletons in the molecule being particularly preferable.

In addition, in the present invention, a host material in which part or all of hydrogen atoms are substituted with heavy hydrogen atoms may be used (Japanese Patent Application Laid-Open (JP-A) No. 2008-126130, Japanese Patent Application Publication (JP-B) No. 2004-515506).

Specific examples of compounds as such hole transporting host materials include the following compounds, but not limited thereto.

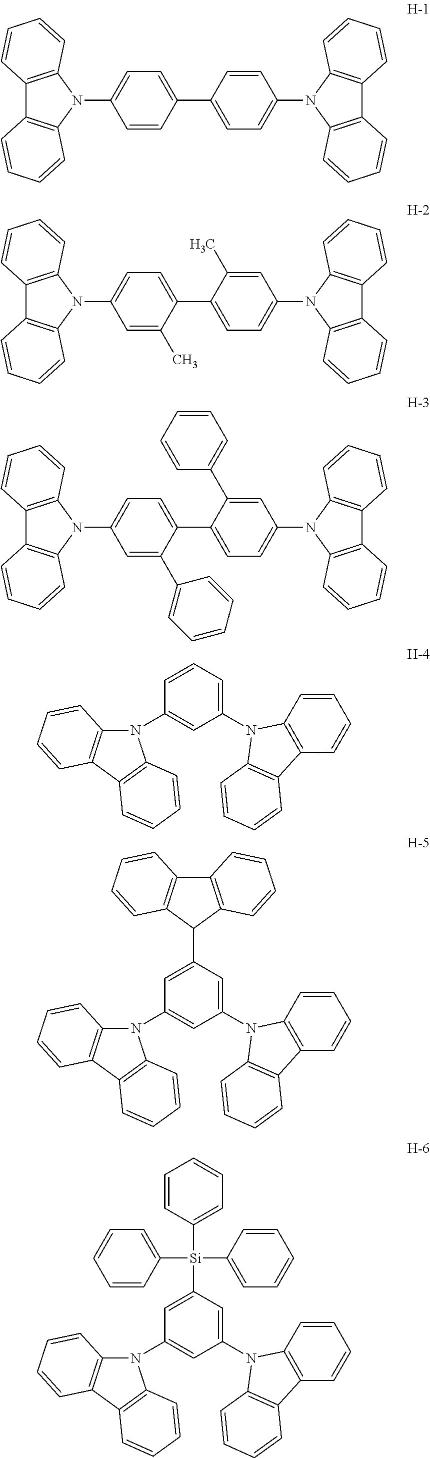

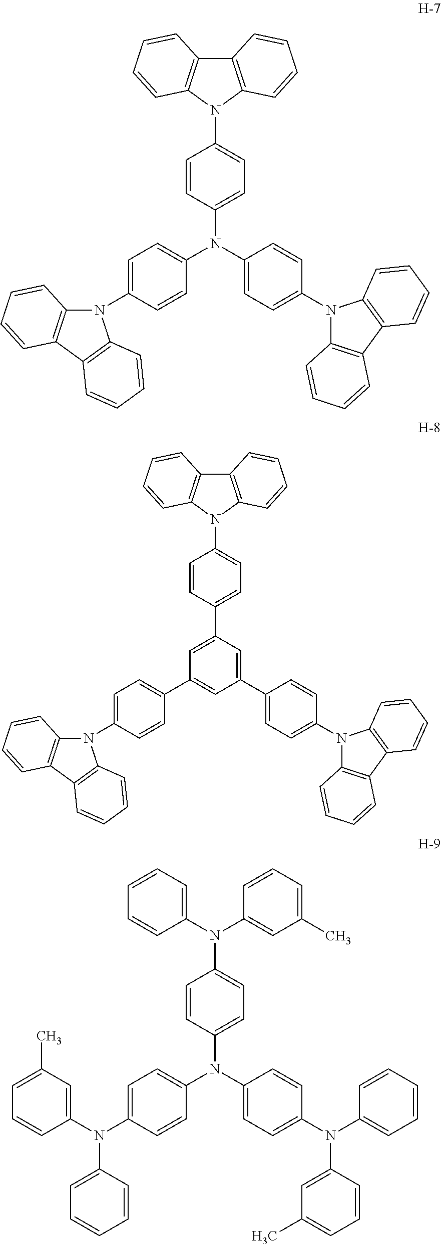

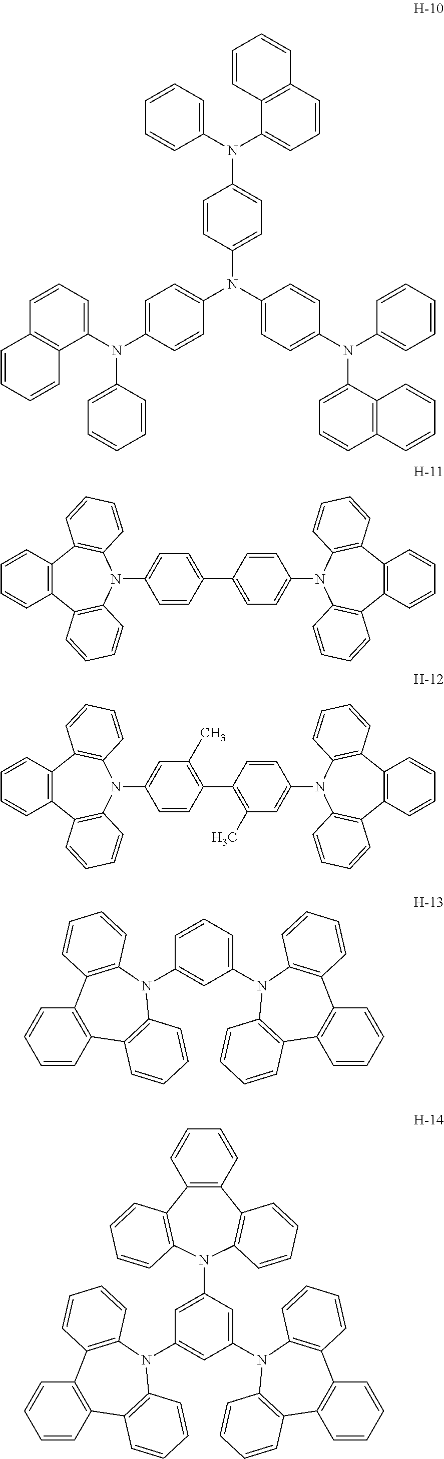

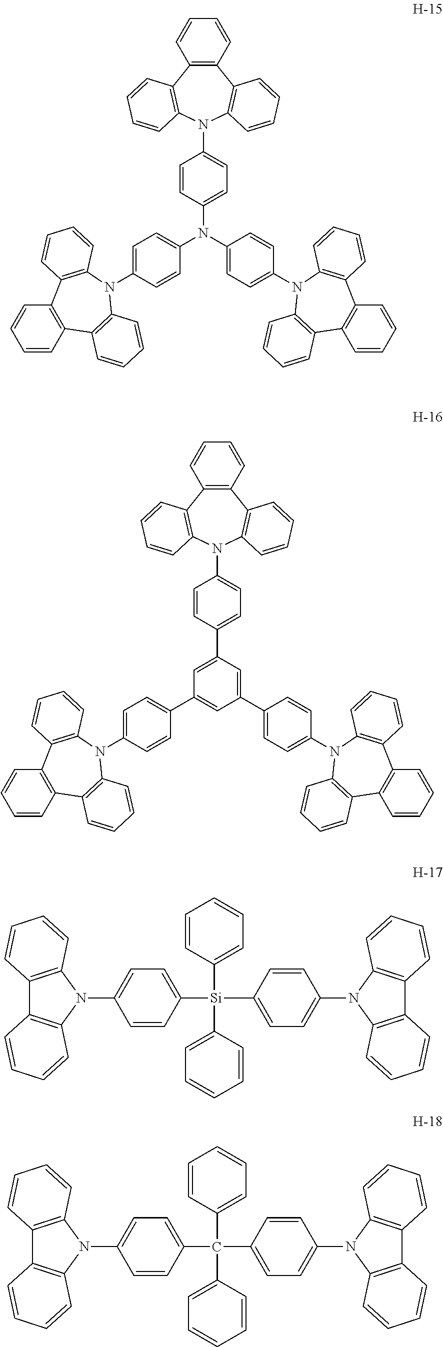

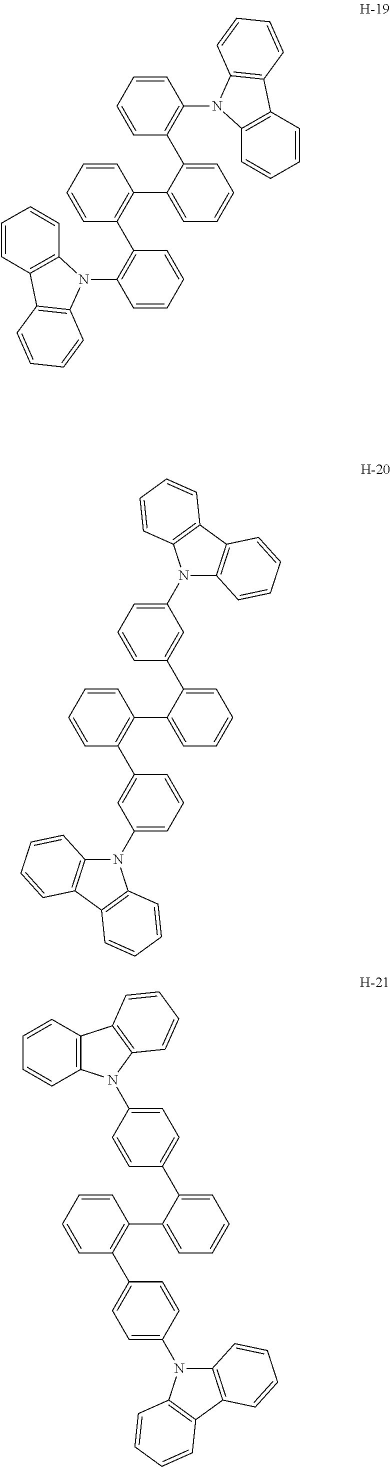

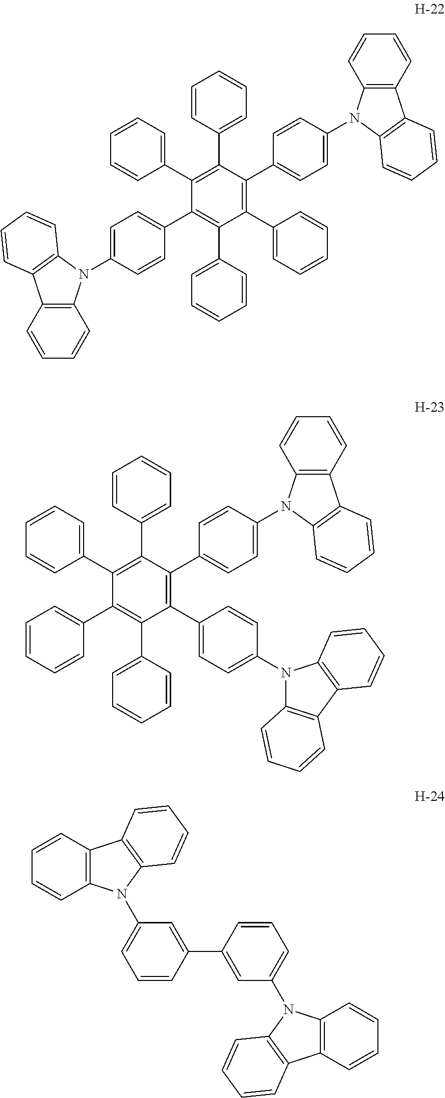

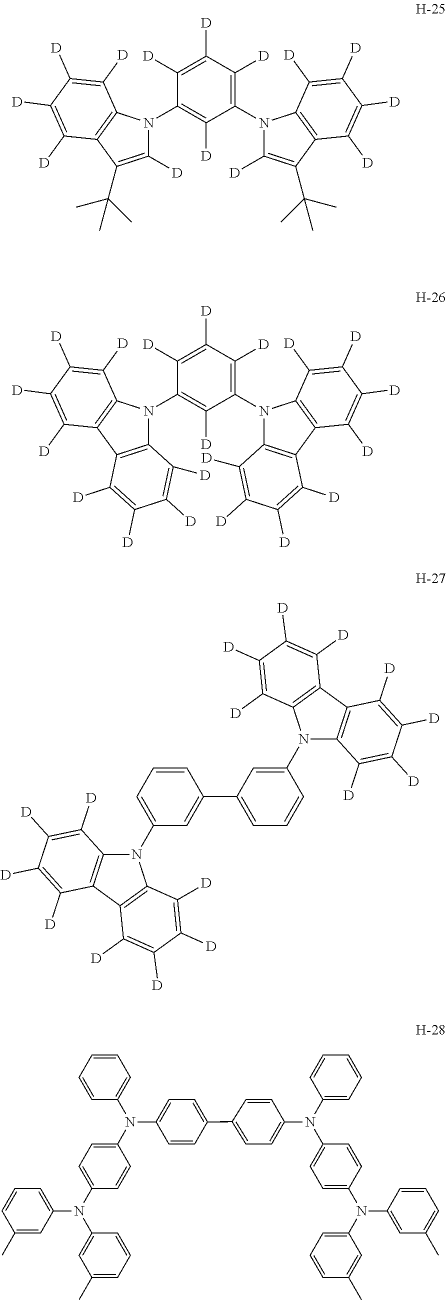

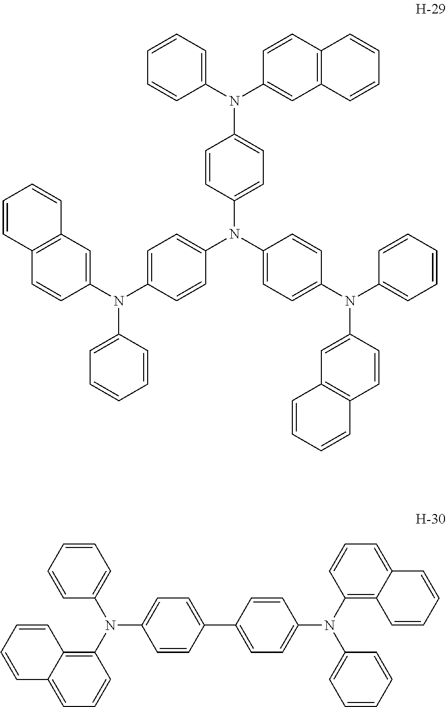

The light emitting layer is a layer having functions to receive, at the time of electric field application, holes from the anode, hole injecting layer or hole transporting layer, and to receive electrons from the cathode, electron injection layer or electron transporting layer, and offer the field of recombination of holes and electrons to emit light.

The light emitting layer can be formed according to a known method, without any particular limitation. The light emitting layer can be appropriately formed, for example, by a dry-process film formation method such as a vapor deposition method and a sputtering method; a wet-process coating method, a transcription method, a printing method, an inkjet method, or the like.

The thickness of the light emitting layer is not particularly limited and may be suitably selected in accordance with the intended use. It is preferably 2 nm to 500 nm, and from the viewpoint of improving the external quantum efficiency, it is more preferably 3 nm to 200 nm, and still more preferably 10 nm to 200 nm. The light emitting layer may be formed of a single layer or two or more layers in which each layer may emit light of a different color.

The organic electroluminescence element of the present invention includes an organic layer including a light emitting layer, between an anode and a cathode.

The organic layer includes at elast the light emitting layer, includes an electron transporting layer, and an electron injection layer, and may include, as required, a hole injection layer, a hole transporting layer, a hole blocking layer, an electron blocking layer, and the like.

### <Electron Injection Layer and Electron Transporting Layer>

The electron injection layer and the electron transporting layer are layers having functions for receiving electrons from a cathode or from a cathode side, and transporting electrons to an anode side.

The electron transporting layer is formed of materials of the electron transporting host material, the electron donating dopant, and the like.

The thickness of the electron injection layer and the electron transporting layer is not particularly limited and may be suitably selected in accordance with the intended use. From the viewpoint of reducing driving voltage, it is preferably 500 nm or less.

The thickness of the electron transporting layer is preferably from 1 nm to 500 nm, more preferably from 5 nm to 200 nm, and still more preferably from 10 nm to 100 nm. The thickness of the electron injection layer is preferably from 0.1 nm to 200 nm, more preferably from 0.2 nm to 100 nm, and still more preferably from 0.5 nm to 50 nm.

The electron injection layer and the electron transporting layer may take a single layer structure containing one or two or more of materials, or a multilayer structure composed of plural layers of a homogeneous composition or a heterogeneous composition.

### <Hole Injection Layer and Hole Transporting Layer>

The hole injection layer and the hole transporting layer are layers functioning to receive holes from an anode or from an anode side and to transport the holes to a cathode side. The hole injection layer and the hole transporting layer may take a single layer structure or a multilayer structure composed of plural layers of a homogeneous composition or a heterogeneous composition. A hole injection material and a hole transporting material for use in these layers may be low-molecular weight compounds or high-molecular weight compounds.

The hole injection material or the hole transporting material is not particularly limited and may be suitably selected in accordance with the intended use. Examples thereof include pyrrole derivatives, carbazole derivatives, triazole derivatives, oxazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, styrylanthracene derivatives, fluorenone derivatives, hydrazone derivatives, stilbene derivatives, silazane derivatives, aromatic tertiary amine compounds, styrylamine compounds, aromatic dimethylidyne compounds, phthalocyanine compounds, porphyrin compounds, thiophene compounds, organic silane derivatives, and carbon. These materials may be used alone or in combination.

An electron-accepting dopant may be introduced into the hole injection layer or the hole transport layer.

As the electron-accepting dopant to be introduced into a hole injection layer or a hole transport layer, either or both of an inorganic compound or an organic compound may be used as long as the compound has electron accepting property and a property for oxidizing an organic compound.

The inorganic compound is not particularly limited and may be suitably selected in accordance with the intended use. Examples thereof include metal halides, such as iron (II) chloride, aluminum chloride, gallium chloride, indium chloride and antimony pentachloride, and metal oxides, such as vanadium pentaoxide, and molybdenum trioxide.

The organic compound is not particularly limited and may be suitably selected in accordance with the intended use. Examples thereof include compounds having a substituent such as a nitro group, a halogen, a cyano group, a trifluoromethyl group or the like; quinone compounds; acid anhydride compounds; fullerenes

These electron accepting dopants may be used alone or in combination. The use amount of the electron accepting dopant varies depending on the type of the material. It is, however, preferably 0.01% by mass to 50% by mass, more preferably 0.05% by mass to 20% by mass, and still more preferably 0.1% by mass to 10% by mass relative to the amount of the hole transporting material or the hole injection material.

The hole injection layer and the hole transporting layer can be appropriately formed by a known method, for example, by a dry-process film formation method such as a vapor deposition method and a sputtering method; a wet-process coating method, a transcription method, a printing method, an inkjet method, or the like.

The thickness of the hole injection layer and the hole transporting layer is preferably 1 nm to 500 nm, more preferably 5 nm to 200 nm, and still more preferably 10 nm to 100 nm.

### <Hole Blocking Layer and Electron Blocking Layer>

The hole blocking layer is a layer having a function to prevent holes transported from the anode side to the light emitting layer from passing through the cathode side. The hole blocking layer is generally provided as an organic compound layer contiguous to the light emitting layer on the cathode side.

The electron blocking layer is a layer having a function to prevent electrons transported from the cathode side to the light emitting layer from passing through the anode side. The electron blocking layer is generally provided as an organic layer contiguous to the light emitting layer on the anode side.

Examples of a compound constituting the hole blocking layer include aluminum complexes such as BAlq, triazole derivatives, and phenanthroline derivatives such as BCP.

As a compound constituting the electron blocking layer, those described as the hole transporting materials can be utilized.

The electron blocking layer and the hole blocking layer may be formed by a known method, without any particular limitation. For example, the electron blocking layer and the hole blocking layer can be appropriately formed by a dry-process film formation method such as a vapor deposition method and a sputtering method; a wet-process coating method, a transcription method, a printing method, an inkjet method, or the like.

The thickness of the hole blocking layer and the electron blocking layer is preferably 1 nm to 200 nm, more preferably 1 nm to 50 nm, and still more preferably 3 nm to 10 nm. In addition, the hole blocking layer and the electron blocking layer may take a single layer structure containing one or two or more of the above-mentioned materials, or a multilayer structure composed of plural layers of a homogeneous composition or a heterogeneous composition.

### <Electrode>

The organic electroluminescence element of the present invention includes a pair of electrodes, that is, an anode and a cathode. In view of the characteristics of the organic electroluminescence element, at least one of the anode and the cathode is preferably transparent. Typically, the anode is sufficient to have a function as an electrode supplying holes to the organic compound layer, and the cathode is sufficient to have a function as an electrode injecting electrons to the organic compound layer.

The electrons are not particularly limited as to the shape, structure, size and the like, and may be suitably selected from known electron materials according to the application and intended use of the organic electroluminescence element.

As materials constituting the electrodes, a metal, an alloy, a metal oxide, a conductive compound, or mixture thereof etc. are preferably exemplified.

### —Anode—

Examples of materials constituting the anode include tin oxides doped with antimony, fluorine, etc. (ATO, FTO); electrically conductive metal oxides such as tin oxide, zinc oxide, indium oxide, indium tin oxide (ITO), and indium zinc oxide (IZO); metals such as gold, silver, chromium, and nickel; mixtures and laminates of these metals with electrically conductive metal oxides; inorganic electrically conductive materials such as copper iodide, and copper sulfide; organic electrically conductive materials such as polyaniline, polythiophene, and polypyrrole; and laminates of these organic electrically conductive materials with ITO, etc. Among these materials, preferred are electrically conductive metal oxides, and ITO is especially preferred from the viewpoint of productivity, high-conductivity, transparency and the like.

### —Cathode—

Examples of materials constituting the cathode include alkali metals (e.g. Li, Na, K, Cs, etc.), alkaline earth metals (e.g. Mg, Ca, etc.), and rare earth metals such as gold, silver, lead, aluminum, sodium-potassium alloy, lithium-aluminum alloy, magnesium-silver alloy, indium, and ytterbium. These materials may be used alone, however, from the viewpoint of simultaneous achievement of stability and electron injection properties, two or more materials can be preferably used in combination.

Among these, as the material constituting the cathode, alkali metals and alkaline earth metals are preferred in terms of the electron injecting property, and materials mainly containing aluminum are preferred for their excellent storage stability.

The materials mainly containing aluminum mean aluminum alone, alloys of aluminum with 0.01% by mass to 10% by mass of alkali metal or alkaline earth metal, or mixtures of these (e.g., lithium-aluminum alloy, magnesium-aluminum alloy, etc.).

The method of forming the electrodes is not particularly limited and may be formed according to a known method. Examples of the forming method include wet-process methods such as a printing method, and a coating method; physical methods such as sputtering and an ion-plating method, and chemical methods such as a CVD method and a plasma CVD method. Among these methods, in view of the applicability with a material constituting the electrodes, the electrodes can be formed on the substrate according to a suitably selected method. For example, when ITO is selected as a material for the anode, the anode can be formed by a direct-current or high-frequency sputtering method, a vacuum deposition method, an ion-plating method, or the like. When metal is selected as a material for the cathode, the cathode can be formed by sputtering or two or more metals simultaneously or sequentially.

Note that when patterning is performed in formation of the electrodes, the patterning of the electrodes may be carried out by chemical etching such as photo-lithography, may be carried out by physical etching with use of a laser, etc., may be carried out by vacuum vapor deposition or sputtering on a superposed mask, or a lift-off method or a printing method may be used.

### <Substrate>

The organic electroluminescence element of the present invention is preferably formed on a substrate, and may be provided in the form where the electrodes are directly contacted with the substrate or an intermediate layer is interposed between the electrodes and the substrate.

A material of the substrate is not particularly limited and may be suitably selected in accordance with the intended use.

Examples of the material of the substrate include inorganic materials, e.g., yttria stabilized zirconia (YSZ), and glass; and organic materials, such as polyester, e.g., polyethylene terephthalate, polybutylene phthalate, and polyethylene naphthalate; polystyrene, polycarbonate, polyether sulfone, polyallylate, polyimide, polycycloolefin, norbornene resin, and poly(chlorotrifluoroethylene).

The shape, structure, size etc. of the substrate are not particularly limited and may be suitably selected in accordance ith the application and intended use of the electroluminescence element. Generally, the substrate is preferably formed in a plate-shape. As the structure of the substrate, it may be a single structure or a multilayer structure, and may consist of a single member or may be formed of two or more members. The substrate may be transparent or opaque. When the substrate is transparent, it may be may be colorless and transparent, or may be colored and transparent.

The substrate can be provided with a moisture permeation preventing layer (a gas barrier layer) on its front surface or rear surface.

As the materials of the moisture permeation-preventing layer (the gas barrier layer), inorganic materials such as silicon nitride and silicon oxide are exemplified.

The moisture permeation-preventing layer (the gas barrier layer) can be formed, for example, by a high frequency sputtering method.

### —Protective Layer—

The organic electroluminescence element may be wholly protected by a protective layer.

The material contained in the protective layer is not particularly limited, as long as it has a function to prevent those accelerating deterioration of the organic electroluminescence element such as moisture and oxygen from entering the organic electroluminescence element, and may be suitably selected in accordance with the intended use. Examples of the material include metals such as In, Sn, Pb, Au, Cu, Ag, Al, Ti, and Ni; metal oxides such as MgO, SiO, SiO₂, Al₂O₃, GeO, NiO, CaO, BaO, Fe₂O₃, Y₂O₃, and TiO₂; metal nitrides such as SiN_{X}, and SiN_{X}O_{y}; metal fluorides such as MgF₂, LiF, AlF₃, and CaF₂; copolymers of dichloroethylene with polyethylene, polypropylene, polymethylmethacrylate, polyimide, polyurea, polytetrafluoroethylene, polychlorotrifluoroethylene, polychlorotrifluoroethylene, polydichlorodifluoroethylene, and/or chlorotrifluoroethylene; a copolymer obtained by copolymerization of tetrafluoroethylene with a monomer mixture containing at least one co-monomer, a fluorine-containing copolymer having a cyclic structure at its copolymer main chain, hydrophilic substances having a coefficient of water absorption of 1% or higher, and water-vaporproof substances having a coefficient of water absorption of 0.1% or lower.

The method of forming the protective layer is not particularly limited and may be suitably selected in accordance with the intended use. For example, there are exemplified a vacuum deposition method, sputtering method, reactive sputtering method, MBE (Molecular Beam epitaxy) method, cluster ion beam method, ion plating method, plasma polymerization method (high-frequency excited ion plating method), plasma CVD method, laser CVD method, thermal CVD method, gas-source CVD method, coating method, printing method, and transcription method.

### —Sealing Container—

The organic electroluminescence element of the present invention may be entirely sealed by a sealing container. Further, in a space between the sealing container and the organic electroluminescence element, a water-absorbing agent or an inactive liquid may be encapsulated.

The water-absorbing agent is not particularly limited and may be suitably selected in accordance with the intended use. Examples thereof include barium oxides, sodium oxides, potassium oxides, calcium oxides, sodium sulfate, calcium sulfate, magnesium sulfate, phosphorus pentoxide, calcium chloride, magnesium chloride, copper chloride, cesium fluoride, niobium fluoride, calcium bromide, vanadium bromide, molecular sieves, zeolite, and magnesium oxide.

The inactive liquid is not particularly limited and may be suitably selected in accordance with the intended use. Examples thereof include paraffins, fluid paraffins, fluorine solvents such as perfluoroalkane, perfluoroamine, and perfluoroether; chlorine solvents, and silicone oils.

### —Resin Sealing Layer—

In the organic electroluminescence element of the present invention, it is preferable to prevent degradation of properties of the organic electroluminescence element due to oxygen and moisture from atmosphere by providing a resin sealing layer.

The resin material of the resin sealing layer is not particularly limited and may be suitably selected in accordance with the intended use. Examples thereof include epoxy resins, fluorine-based resins, silicone-based resins, rubber-based resins, and ester-based resins. Among these materials, epoxy resins are particularly preferable from the viewpoint of the water-proof function.

The method of producing the resin sealing layer is not particularly limited and may be suitably selected in accordance with the intended use. Examples of the method include a method of applying a resin solution, a method of pressing or thermally pressing a resin sheet, and a dry-process polymerization method such as a vapor deposition method and sputtering.

### —Sealing Adhesive—

A sealing adhesive for use in the present invention has a function to prevent moisture and oxygen from entering the organic electroluminescence element from its distal ends thereof.

As materials for the sealing adhesive, the same materials for the resin sealing layer can be used. Among the materials, in view of prevention of moisture, preferred is an epoxy-based adhesive, and more preferred are a photocurable adhesive and a thermocurable adhesive.

Further, it is preferred to add a filler to the sealing adhesive. As a filler to be added to the sealing agent, inorganic materials such as SiO₂, SiO (silicon oxide), SiON (silicon oxynitride), SiN (silicone nitride) and the like are preferred. By adding a filler to the sealing agent, the viscosity of the sealing agent is increased, leading to improvements in process suitability and humidity resistance.

The sealing adhesive may contain a desiccating agent. As the desiccating agent, barium oxides, calcium oxides, strontium oxides are exemplified. The amount of the desiccating agent added to the sealing agent is preferably 0.01% by mass to 20% by mass, more preferably 0.05% by mass to 15% by mass. When the addition amount is less than 0.01% by mass, the effect of adding the desiccating agent is reduced. When the addition amount is more than 20% by mass, it is undesirably difficult to homogenously disperse the desiccating agent in the sealing adhesive.

In the present invention, the sealing adhesive in which he desiccating agent has been contained is applied in an optional amount by a dispenser or the like, and thereafter, a second substrate is superposed on the workpiece, followed by curing, to thereby the organic electroluminescence elopement can be sealed.

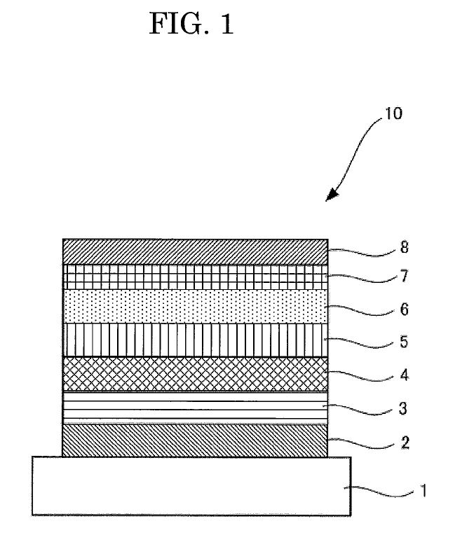

FIG. 1 is a schematic diagram illustrating one example of a layer configuration of the organic electroluminescence element of the present invention. An organic EL element 10 has a layer configuration where an anode 2 (e.g., ITO electrode) formed on a glass substrate 1, a hole injection layer 3, a hole transporting layer 4, a light emitting layer 5, an electron transporting layer 6, an electron injection layer 7, and a cathode 8 (e.g., Al—Li electrode) are laminated in this order. Note that the anode 2 (e.g., ITO electrode) and the cathode 8 (e.g., Al—Li electrode) are connected to each other via a power source.

### —Driving—

By the application of DC (if necessary, AC component may be contained) voltage (generally from 2 volts to 15 volts) between the anode and the cathode, or by the application of DC electric current, light emission of the organic electroluminescence element of the invention can be obtained.

The organic electroluminescence element of the present invention can be used for an active matrix through a thin film transistor (TFT). As a material for use in an active layer of the thin film transistor, an amorphous silicon, a high-temperature polysilicon, a low-temperature polysilicon, a microcrystal silicon, an oxide semiconductor, an organic semiconductor, a carbon nanotube or the like can be used.

In the organic electroluminescence element of the present invention, thin film transistors described, for example, in WO2005/088726, Japanese Patent Application Laid-Open (JP-A) No. 2006-165529, U.S. Patent Application No. 2008/0237598A1 etc. can be used.

The organic electroluminescence element of the present invention can be improved in the efficiency of extraction of light by various known contrivances, without no particular limitation. For example, it is possible to improve the efficiency of extraction of light and improve external quantum efficiency by processing the shape of the substrate surface (for example, by forming a minute concave-convex pattern), by controlling the refractive indices of the substrate, ITO layer and organic layer, and by controlling the thicknesses of the substrate, ITO layer and organic layer.

Light extraction from the organic electroluminescence element of the present invention may be a top emission system or a bottom emission system.

The organic electroluminescence element may have a resonator structure.

For example, the organic electroluminescence element has a multilayer film mirror including a plurality of laminated films different in refractive index, a transparent or translucent electrode, a light emitting layer, and a metal electrode by superposition on a transparent substrate. The light generated from the light emitting layer repeats reflection and resonates between the multilayer film mirror and the metal electrode as reflectors.

As another preferred embodiment, a transparent or translucent electrode and a metal electrode respectively function as reflectors on a transparent substrate, and light generated from the light emitting layer repeats reflection and resonates between them.

To form a resonance structure, effective refractive indices of two reflectors, optical path determined by the refractive index and thickness of each layer between the reflectors are adjusted to be optimal values to obtain a desired resonance wavelength. The expression of the case of the first embodiment is disclosed in Japanese Patent Application Laid-Open (JP-A) No. 09-180883. The expression of the case of the second embodiment is disclosed in Japanese Patent Application Laid-Open (JP-A) No. 2004-127795.

### —Application—

Application of the organic electroluminescence element of the present invention is not particularly limited and may be suitably selected in accordance with the intended use. For example, the organic electroluminescence element of the present invention can be suitably utilized in display devices, displays, back light, electrophotography, illumination light sources, recording light sources, exposure light sources, reading light sources, signs, advertizing sign boards, interiors, optical communication, etc.

As a method of making the organic EL display device full colors, for example, as described in Monthly Display, pp. 33-37 (September, 2000), a three-color light-emitting method of arranging organic EL elements emitting lights corresponding to three primary colors (blue (B), green (G) and red (R)) of colors on a substrate, a white color method of separating white color emission by an organic EL element for white color emission to three colors through a color filter, and a color-converting method of converting blue color emission by an organic EL element for blue color emission to red (R) and green (G) through a fluorescent dye layer are known. Further, by using in combination of a plurality of organic EL elements different in luminescent colors capable of obtaining by the above method, plane light sources of desired luminescent colors can be obtained. For example, a white emission light source of combining luminescence devices of blue and yellow luminescence devices, and a white emission light source of combining luminescence devices of blue, green and red are exemplified.

### EXAMPLES

Hereinafter, the present invention will be described with reference to Examples, which, however, shall not be construed as limiting the scope of the present invention.

### Comparative Example 1

### Production of Organic Electroluminescence Element

A 0.5-mm thickness and 2.5-cm square glass substrate was placed in a washing container, and subjected to ultrasonic wave washing with 2-propanol, followed by UV-ozone treatment for 30 minutes. Then, the following individual layers were vapor deposited on the glass substrate by a vacuum vapor deposition method. Note that the deposition rate employed in the following Examples and Comparative Examples is 0.2 nm/sec, unless otherwise specified. The deposition rate was measured by a quartz oscillator. In addition, the thickness of each of the following layers was measured by a quartz oscillator.

Firstly, on the glass substrate, ITO (Indium Tin Oxide) was deposited as an anode by sputtering in a thickness of 100 nm.

Next, on the anode (ITO), 2-TNATA(4,4′,4″-Tris(N-(2-naphtyl)-N-phenyl-amino)-triphenylamine) was deposited as a hole injection layer in a thickness of 140 nm.

Next, on the hole injection layer, α-NPD(Bis[N-(1-naphthyl)-N-pheny]benzidine) was deposited as a hole transporting layer in a thickness of 7 nm.

Next, on the hole transporting layer, Amine Compound 1 represented by the following structural formula was deposited as a second hole transporting layer in a thickness of 3 nm.

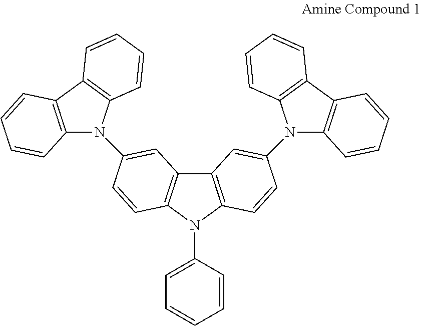

Next, on the second hole transporting layer, a light emitting layer in which H-4[mCP;(N,N′-dicarbazolyl-3,5-benzene)] represented by the following structural formula and serving as a hole transporting host material was doped with 6.0% by mass of Firpic[iridium(III)bis[4,6-di-fluorophenyl]-pyridinato-)picolinate] serving as a hole-transporting phosphorous light emitting material, was deposited in a thickness of 30 nm.

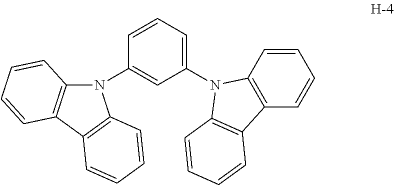

Next, on the light emitting layer, Nitrogen-Containing Heterocyclic Derivative 1 serving as a high electron transporting material represented by the following structural formula and contained in General Formula (1) was deposited as an electron transporting layer in a thickness of 40 nm.

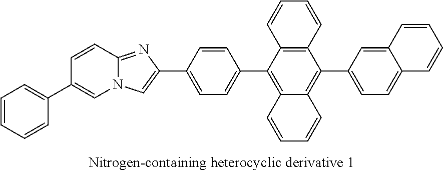

Next, on the electron transporting layer, LiF was deposited as an electron injecting layer so as to have a thickness of 1 nm.

Next, on the electron injecting layer, a mask patterned as a cathode (a mask allowing a light emission area to be 2 mm×2 mm) was disposed, and then a metal aluminum was deposited in a thickness of 100 nm.

A laminated produced by the above process was placed in a groove box purged with argon gas and sealed using a stainless-steel sealing can and a ultraviolet-curable adhesive (XNR5516HV, produced by Nagase Chemtex Corp.), and thereby an organic electroluminescence element of Comparative Example 1 was produced.

### Comparative Example 2

### Production of Organic Electroluminescence Element

An organic electroluminescence element was produced in the same manner as in Comparative Example 1, except that BAlq[Bis-(2-methyl-8-quinolinolato)-4-(phenyl-phenolate)-aluminum-(III)] serving as a low electron transporting material was used as an electron transporting layer.

### Comparative Example 3

### Production of Organic Electroluminescence Element

An organic electroluminescence element was produced in the same manner as in Comparative Example 2, except that D-1 serving as an electron-transporting phosphorous light emitting material represented by the following structural formula contained in General Formula (2) was used as a light emitting material.

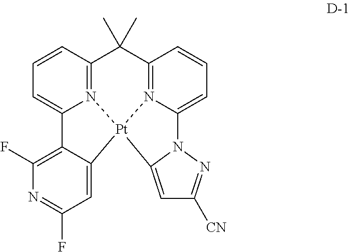

### Example 1

### Production of Organic Electroluminescence Element

An organic electroluminescence element was produced in the same manner as in Comparative Example 1, except that D-1 represented by the above-described structural formula was used as a light emitting material, instead of Firpic.

### Example 2

### Production of Organic Electroluminescence Element

An organic electroluminescence element was produced in the same manner as in Example 1, except that Nitrogen-containing heterocyclic derivative 2 represented by the following structural formula was used as an electron transporting layer.

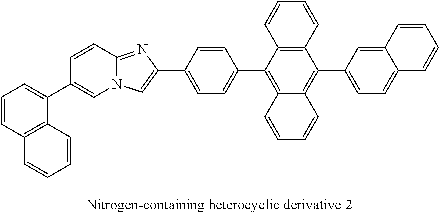

### Example 3

### Production of Organic Electroluminescence Element

An organic electroluminescence element was produced in the same manner as in Example 1, except that Nitrogen-containing heterocyclic derivative 3 represented by the following structural formula was used as an electron transporting layer.

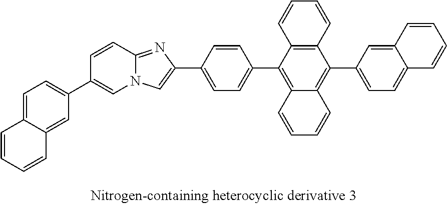

### Example 4

### Production of Organic Electroluminescence Element

An organic electroluminescence element was produced in the same manner as in Example 1, except that Nitrogen-containing heterocyclic derivative 4 represented by the following structural formula was used as an electron transporting layer.

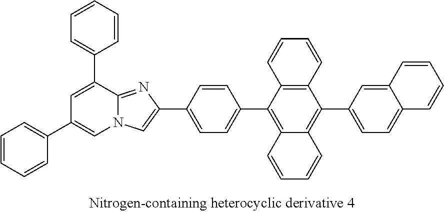

### Example 5

### Production of Organic Electroluminescence Element

An organic electroluminescence element was produced in the same manner as in Example 1, except that D-2 represented by the following structural formula was used as a light emitting material.

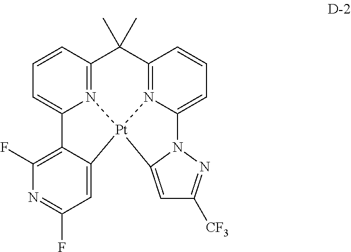

### Example 6

### Production of Organic Electroluminescence Element

An organic electroluminescence element was produced in the same manner as in Example 5, except that H-24 represented by the following structural formula 2 was used as a host material and Nitrogen-containing heterocyclic derivative 2 represented by the above-described structural formula was used as an electron transporting layer.

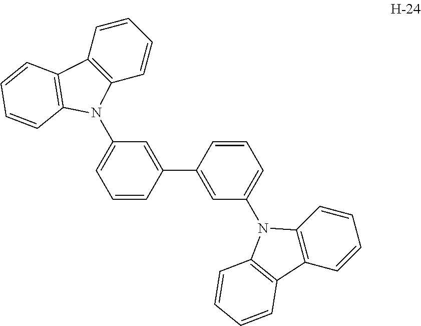

### Example 7

### Production of Organic Electroluminescence Element

An organic electroluminescence element was produced in the same manner as in Example 5, except that H-27 represented by the following structural formula was used as a host material and Nitrogen-containing heterocyclic derivative 3 represented by the above-described structural formula was used as an electron transporting layer.

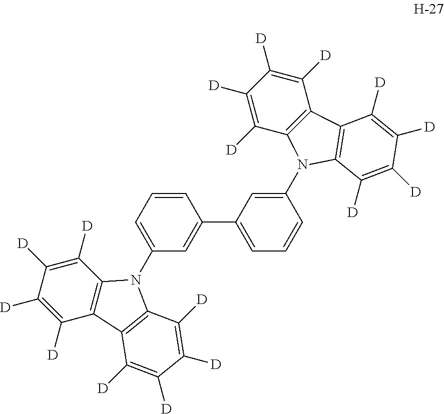

### Example 8

### Production of Organic Electroluminescence Element

An organic electroluminescence element was produced in the same manner as in Example 1, except that H-17 represented by the following structural formula was used as a host material, D-3 represented by the following structural formula was used as a light emitting material, and Nitrogen-containing heterocyclic derivative 4 represented by the above-described structural formula was used as an electron transporting layer.

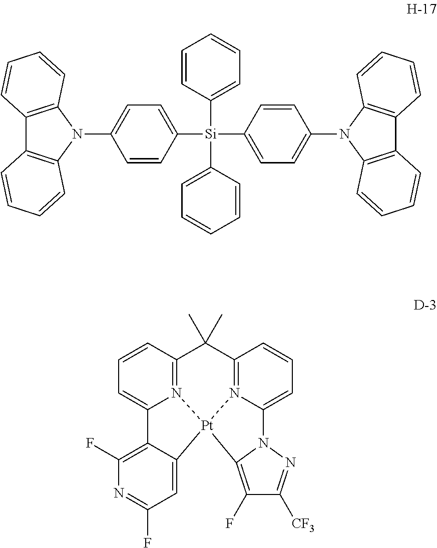

### Example 9

### Production of Organic Electroluminescence Element

An organic electroluminescence element was produced in the same manner as in Example 1, except that D-4 represented by the following structural formula was used as a light emitting material.

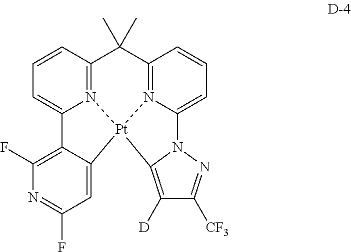

### Example 10

### Production of Organic Electroluminescence Element

An organic electroluminescence element was produced in the same manner as in Example 9, except that H-24 represented by the following structural formula was used as a host material, and Nitrogen-containing heterocyclic derivative 2 represented by the above-described structural formula was used as an electron transporting layer.

### Example 11

### Production of Organic Electroluminescence Element

An organic electroluminescence element was produced in the same manner as in Example 1, except that D-5 represented by the following structural formula was used as a light emitting material, and Nitrogen-containing heterocyclic derivative 3 represented by the above-described structural formula was used as an electron transporting layer.

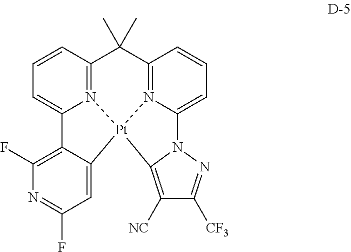

### Example 12

### Production of Organic Electroluminescence Element

An organic electroluminescence element was produced in the same manner as in Example 1, except that D-9 represented by the following structural formula was used as a light emitting material, and Nitrogen-containing heterocyclic derivative 4 represented by the above-described structural formula was used as an electron transporting layer.

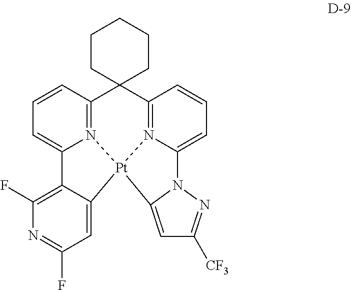

### Example 13

### Production of Organic Electroluminescence Element

An organic electroluminescence element was produced in the same manner as in Example 12, except that Nitrogen-containing heterocyclic derivative 1 represented by the above-described structural formula was used as an electron transporting layer.

### Example 14

### Production of Organic Electroluminescence Element

An organic electroluminescence element was produced in the same manner as in Example 2, except that D-10 represented by the following structural formula was used as a light emitting material

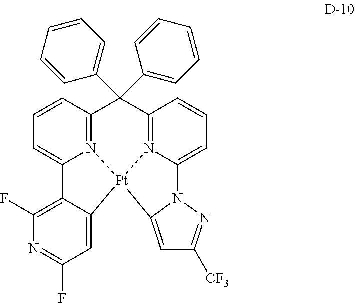

### Example 15

### Production of Organic Electroluminescence Element

An organic electroluminescence element was produced in the same manner as in Example 14, except that Nitrogen-containing heterocyclic derivative 3 represented by the above-described structural formula was used as an electron transporting layer.

### Example 16

### Production of Organic Electroluminescence Element

An organic electroluminescence element was produced in the same manner as in Example 4, except that D-14 represented by the following structural formula was used as a light emitting material

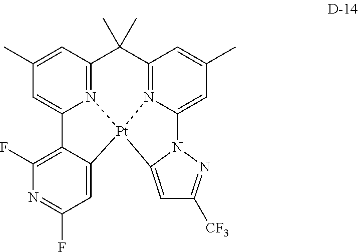

### Example 17

### Production of Organic Electroluminescence Element

An organic electroluminescence element was produced in the same manner as in Example 1, except that D-15 represented by the following structural formula was used as a light emitting material

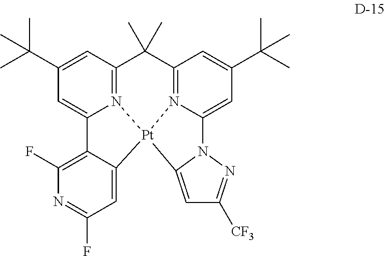

### Example 18

### Production of Organic Electroluminescence Element

An organic electroluminescence element was produced in the same manner as in Example 2, except that D-23 represented by the following structural formula was used as a light emitting material

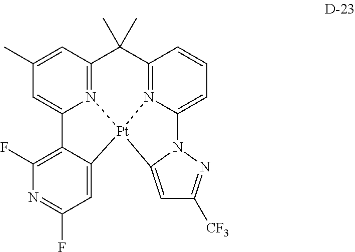

### Example 19

### Production of Organic Electroluminescence Element

An organic electroluminescence element was produced in the same manner as in Example 3, except that D-24 represented by the following structural formula was used as a light emitting material

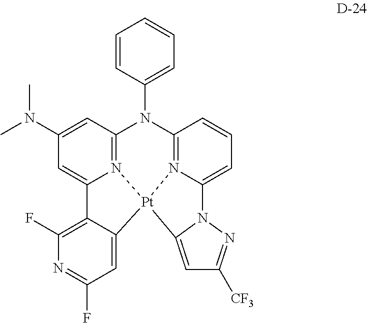

### Example 20

### Production of Organic Electroluminescence Element

An organic electroluminescence element was produced in the same manner as in Example 19, except that Nitrogen-containing heterocyclic derivative 4 represented by the above-described structural formula was used as an electron transporting layer.

Next, as for the organic electroluminescence elements produced in Examples 1 to 20 and Comparative Examples 1 to 3, the driving voltage and external quantum efficiency were measured. Table 1 shows the measurement results.

### <Measurement of Driving Voltage>

SOURCE MEASURE UNIT 2400 manufactured by Toyo Technica Co. was used and a direct-current voltage was applied to each of the organic electroluminescence elements to allow it to emit light. The voltage when the current was 10 mA/cm² was measured as its driving voltage.

### <Measurement of External Quantum Efficiency>

SOURCE MEASURE UNIT 2400 manufactured by Toyo Technica Co. was used and a direct-current voltage was applied to each of the organic electroluminescence elements to allow it to emit light. A light emission spectrum and luminance were measured using a spectrum analyzer SR-3 manufactured by TOPCON Corp., and based on these measured values, the external quantum efficiency at which the current was 10 mA/cm² was calculated by the luminance conversion method.

TABLE 1

| | | | | | External |
|---|---|---|---|---|---|
| | | Light | Electron | Driving | quantum |
| | Host | emitting | transporting | voltage (V) | efficiency (%) |
| | material | material | material | 10 mA/cm² | 10 mA/cm² |
| Comp. | H-4 | Firpic | Derivative 1 | 4.8 | 5 |
| Ex. 1 | | | | | |
| Comp. | H-4 | Firpic | BAlq | 6.0 | 8 |
| Ex. 2 | | | | | |
| Comp. | H-4 | D-1 | BAlq | 5.8 | 12 |
| Ex. 3 | | | | | |
| Ex. 1 | H-4 | D-1 | Derivative 1 | 4.6 | 13 |
| Ex. 2 | H-4 | D-1 | Derivative 2 | 4.8 | 12 |
| Ex. 3 | H-4 | D-1 | Derivative 3 | 4.6 | 12 |
| Ex. 4 | H-4 | D-1 | Derivative 4 | 4.9 | 13 |
| Ex. 5 | H-4 | D-2 | Derivative 1 | 4.8 | 14 |
| Ex. 6 | H-24 | D-2 | Derivative 2 | 4.8 | 14 |
| Ex. 7 | H-27 | D-2 | Derivative 3 | 4.6 | 15 |
| Ex. 8 | H-17 | D-3 | Derivative 4 | 4.7 | 12 |
| Ex. 9 | H-4 | D-4 | Derivative 1 | 4.5 | 11 |
| Ex. 10 | H-24 | D-4 | Derivative 2 | 4.6 | 11 |
| Ex. 11 | H-4 | D-5 | Derivative 3 | 4.6 | 13 |
| Ex. 12 | H-4 | D-9 | Derivative 4 | 4.7 | 10 |
| Ex. 13 | H-4 | D-9 | Derivative 1 | 4.6 | 10 |
| Ex. 14 | H-4 | D-10 | Derivative 2 | 4.7 | 13 |
| Ex. 15 | H-4 | D-10 | Derivative 3 | 4.8 | 13 |
| Ex. 16 | H-4 | D-14 | Derivative 4 | 4.7 | 9 |
| Ex. 17 | H-4 | D-15 | Derivative 1 | 4.7 | 12 |
| Ex. 18 | H-4 | D-23 | Derivative 2 | 4.5 | 11 |
| Ex. 19 | H-4 | D-24 | Derivative 3 | 4.6 | 12 |
| Ex. 20 | H-4 | D-24 | Derivative 4 | 4.8 | 12 |

From the results shown in Table 1, it can be seen that when Comparative Example 1 was compared to Comparative Example 2, in the case of using Firpic serving as a hole-transporting phosphorescence emission material was used and the material of an electron transporting layer was changed from BAlq serving as a low-electron transporting material to Nitrogen-containing heterocyclic derivative 1 serving as a high-electron transporting material, the driving voltage was surely reduced, but a reduction in external quantum efficiency was caused, and the effect of high-quantum efficiency and low-voltage brought by the phosphorous light emitting material could not be simultaneously achieved.

However, when Comparative Example 3 using the platinum complex containing a tetradentate ligand (D-1) serving as an electron transporting phosphorous light emitting material to Example 1, a significant lower voltage effect could be seen by changing the electron transporting layer material from BAlq to Nitrogen-containing heterocyclic derivative 1, and further high external quantum efficiency could be maintained. In addition, in Examples 2 to 4, similar effects were recognized in three types of Nitrogen-containing heterocyclic derivatives, and in Examples 5 to 20, similar effects were recognized in the electron-transporting phosphorous light emitting material satisfying General Formula (2).

### Comparative Example 4

### Production of Organic Electroluminescence Element

An organic electroluminescence element was produced in the same manner as in Comparative Example 1, except that 2-TNATA used as the hole injecting layer was changed to DNTPD(N,N′-bis-[4-(di-m-tolylamino)phenyl]-N,N′-diphenylbiphenyl-4,4′-diamine).

### Example 21

### Production of Organic Electroluminescence Element

An organic electroluminescence element was produced in the same manner as in Comparative Example 4, except that Firpic used as a light emitting material was changed to D-1 represented by the following structural formula.

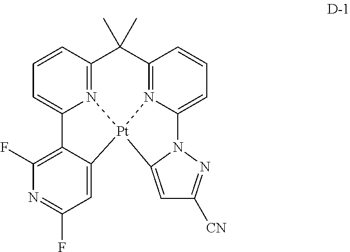

### Example 22

### Production of Organic Electroluminescence Element

An organic electroluminescence element was produced in the same manner as in Comparative Example 21, except that Nitrogen-containing heterocyclic derivative 2 represented by the following structural formula was used as an electron transporting layer.

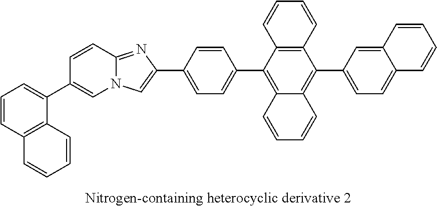

### Example 23

### Production of Organic Electroluminescence Element

An organic electroluminescence element was produced in the same manner as in Comparative Example 21, except that Nitrogen-containing heterocyclic derivative 3 represented by the following structural formula was used as an electron transporting layer.

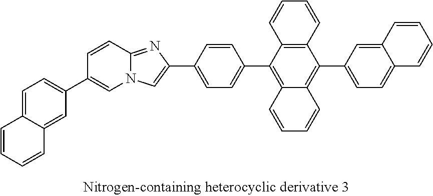

As for the resulting organic electroluminescence elements of Comparative Example 4 and Examples 21 to 23, the driving voltage and external quantum efficiency were measured according to the same procedures. Table 2 shows the measurement results.

TABLE 2

| | | | | | External |
|---|---|---|---|---|---|
| | | Light | Electron | Driving | quantum |
| | Host | emitting | transporting | voltage (V) | efficiency (%) |
| | material | material | material | 10 mA/cm² | 10 mA/cm² |
| Comp. | H-4 | Firpic | Derivative 1 | 4.8 | 5 |
| Ex. 4 | | | | | |
| Ex. 21 | H-4 | D-1 | Derivative 1 | 4.6 | 13 |
| Ex. 22 | H-4 | D-1 | Derivative 2 | 4.8 | 12 |
| Ex. 23 | H-4 | D-1 | Derivative 3 | 4.6 | 12 |

### INDUSTRIAL APPLICABILITY

Since the organic electroluminescence element of the present invention enables reducing voltage in drying voltage and maintaining high light emission efficiency, it can be suitably utilized, for example, in display devices, displays, back light, electrophotography, illumination light sources, recording light sources, exposure light sources, reading light sources, signs, advertizing sign boards, interiors, optical communication, etc.

1. An organic electroluminescence element comprising:
at least one organic layer including a light emitting layer, between an anode and a cathode,
wherein at least one layer of the at least one organic layer contains at least one selected from nitrogen-containing heterocyclic derivatives represented by General Formula (1) below, and at least one layer of the at least one organic layer contains an electron-transporting phosphorous light emitting material represented by General Formula (2) below, 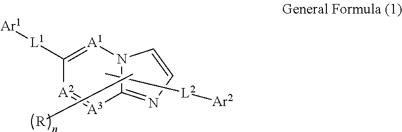
where A¹ to A³ each independently represent a nitrogen atom or a carbon atom, Ar¹ represents a substituted or unsubstituted aryl group having nucleus carbon atoms of 6 to 60 or a substituted or unsubstituted heteroaryl group having nucleus carbon atoms of 3 to 60, Ar² represents a hydrogen atom, a substituted or unsubstituted aryl group having nucleus carbon atoms of 6 to 60, a substituted or unsubstituted heteroaryl group having nucleus carbon atoms of 3 to 60, a substituted or unsubstituted alkyl group having 1 to 20 carbon atoms or a substituted or unsubstituted alkoxy group having 1 to 20 carbon atoms, wherein one of Ar¹ and Ar² is a substituted or unsubstituted condensed ring group having 10 to 60 nucleus carbon atoms or a substituted or unsubstituted monohetero condensed ring group having 3 to 60 nucleus carbon atoms; L¹ and L² each independently represent a single bond, a substituted or unsubstituted arylene group having 6 to 60 nucleus carbon atoms, a substituted or unsubstituted heteroarylene group having 3 to 60 nucleus carbon atoms or a substituted or unsubstituted fluorenylene group; R represents a hydrogen atoms, a substituted or unsubstituted aryl group having 6 to 60 nucleus carbon atoms, a substituted or unsubstituted heteroaryl group having nucleus carbon atoms of 3 to 60, a substituted or unsubstituted alkyl group having 1 to 20 carbon atoms or a substituted or unsubstituted alkoxy group having 1 to 20 carbon atoms; and n is an integer of 0 to 5, when n is 2 or greater, a plurality of Rs may be different from or identical to each other, and adjacent R groups among the plurality of Rs may be bonded to form a carbocyclic aliphatic ring or a carbocyclic aromatic ring, 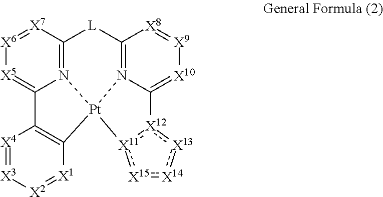
where X¹, X², X³ and X⁴ each independently represent a carbon atom or a nitrogen atom, and one or more selected from X¹, X², X³ and X⁴ represents or represent a nitrogen atom; X⁵, X⁶, X⁷, X⁸, X⁹ and X¹⁰ each independently represent a carbon atom or a nitrogen atom; X¹¹ and X¹² each independently represent a carbon atom or a nitrogen atom; X¹³, X¹⁴ and X¹⁵ each independently represent a carbon atom, a nitrogen atom, an oxygen atom or a sulfur atom, the number of nitrogen atoms contained in a five-membered ring skeleton represented by any one of X¹¹, X¹², X¹³, X¹⁴ and X¹⁵ is 2 or smaller; and L represents a single bond or a divalent linking group.

2. The organic electroluminescence element according to claim 1, wherein at least one selected from the nitrogen-containing heterocyclic derivatives represented by General Formula (1) is a nitrogen-containing heterocyclic derivative represented by General Formula (3) below, 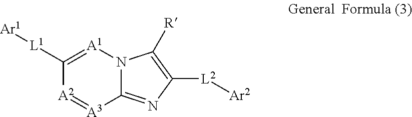
where A¹ to A³ each independently represent a nitrogen atom or a carbon atom, Ar¹ represents a substituted or unsubstituted aryl group having nucleus carbon atoms of 6 to 60 or a substituted or unsubstituted heteroaryl group having nucleus carbon atoms of 3 to 60, Ar² represents a hydrogen atom, a substituted or unsubstituted aryl group having nucleus carbon atoms of 6 to 60, a substituted or unsubstituted heteroaryl group having nucleus carbon atoms of 3 to 60, a substituted or unsubstituted alkyl group having 1 to 20 carbon atoms or a substituted or unsubstituted alkoxy group having 1 to 20 carbon atoms, wherein one of Ar¹ and Ar² is a substituted or unsubstituted condensed ring group having nucleus carbon atoms of 10 to 60 or a substituted or unsubstituted monohetero condensed ring group having nucleus carbon atoms of 3 to 60; L¹ and L² each independently represent a single bond, a substituted or unsubstituted arylene group having 6 to 60 nucleus carbon atoms, a substituted or unsubstituted heteroarylene group having 3 to 60 nucleus carbon atoms or a substituted or unsubstituted fluorenylene group; and R′ represents a hydrogen atom, a substituted or unsubstituted aryl group having 6 to 60 nucleus carbon atoms, a substituted or unsubstituted heteroaryl group having 3 to 60 nucleus carbon atoms, a substituted or unsubstituted alkyl group having 1 to 20 carbon atoms or a substituted or unsubstituted alkoxy group having 1 to 20 carbon atoms.

3. The organic electroluminescence element according to claim 2, wherein the nitrogen-containing heterocyclic derivative represented by General Formula (3) is a nitrogen-containing heterocyclic derivative represented by General Formula (4). 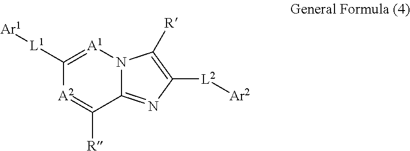
where A¹ and A² each independently represent a nitrogen atom or a carbon atom, Ar¹ represents a substituted or unsubstituted aryl group having nucleus carbon atoms of 6 to 60 or a substituted or unsubstituted heteroaryl group having nucleus carbon atoms of 3 to 60, Ar² represents a hydrogen atom, a substituted or unsubstituted aryl group having nucleus carbon atoms of 6 to 60, a substituted or unsubstituted heteroaryl group having nucleus carbon atoms of 3 to 60, a substituted or unsubstituted alkyl group having 1 to 20 carbon atoms or a substituted or unsubstituted alkoxy group having 1 to 20 carbon atoms, wherein one of Ar¹ and Ar² is a substituted or unsubstituted condensed ring group having 10 to 60 nucleus carbon atoms or a substituted or unsubstituted monohetero condensed ring group having 3 to 60 nucleus carbon atoms; L¹ and L² each independently represent a single bond, a substituted or unsubstituted arylene group having 6 to 60 nucleus carbon atoms, a substituted or unsubstituted heteroarylene group having 3 to 60 nucleus carbon atoms or a substituted or unsubstituted fluorenylene group; and R′ and R″ each independently represent a hydrogen atom, a substituted or unsubstituted aryl group having 6 to 60 nucleus carbon atoms, a substituted or unsubstituted heteroaryl group having 3 to 60 nucleus carbon atoms, a substituted or unsubstituted alkyl group having 1 to 20 carbon atoms or a substituted or unsubstituted alkoxy group having 1 to 20 carbon atoms, R′ and R″ may be different from or identical to each other.

4. The organic electroluminescence element according to claim 1, wherein in the nitrogen-containing heterocyclic derivative represented by any one of General Formulae (1), (3) and (4), at least one of L¹ and L² is selected from groups each independently represented by Structural Formulae below:

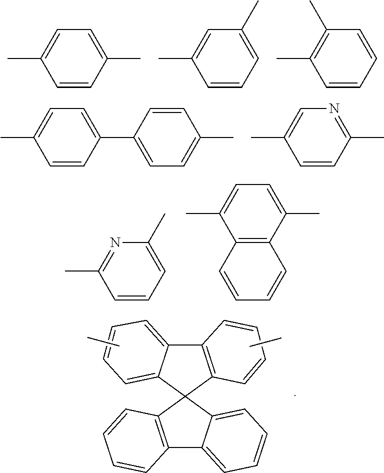

5. The organic electroluminescence element according to claim 1, wherein in the nitrogen-containing heterocyclic derivative represented by any one of General Formulae (1), (3) and (4), Ar¹ is a group represented by any one of General Formulae (5) to (14) below: 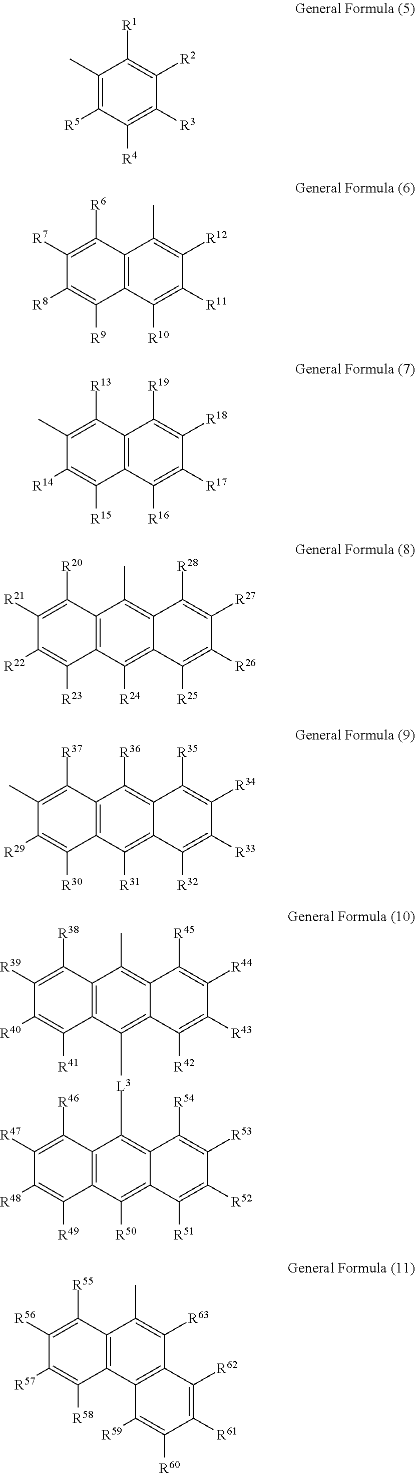 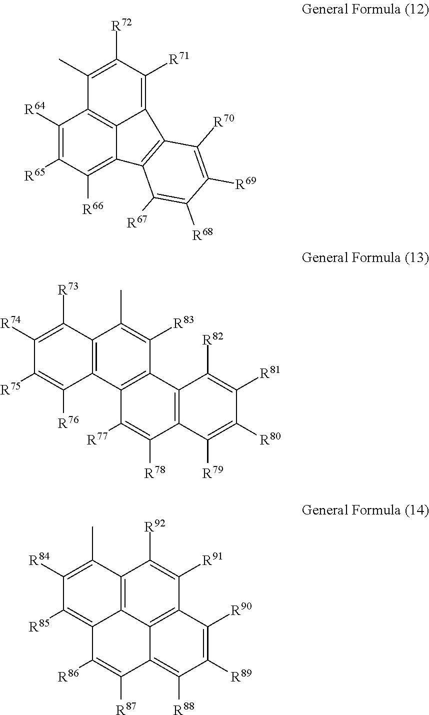
where R¹ to R⁹² each independently represent a hydrogen atom, a halogen atom, a substituted or unsubstituted alkyl group having 1 to 20 carbon atoms, a substituted or unsubstituted alkoxy group having 1 to 20 carbon atoms, a substituted or unsubstituted aryloxy group having 6 to 40 nucleus carbon atoms, a substituted or unsubstituted diarylamino group having 12 to 80 nucleus carbon atoms, a substituted or unsubstituted aryl group having 6 to 40 nucleus carbon atoms, a substituted or unsubstituted heteroaryl group having 3 to 40 nucleus carbon atoms, or a substituted or unsubstituted diarylaminoaryl group having 18 to 120 nucleus carbon atoms; and L³ represents a single bond or a substituent represented by any one of Structural Formulae below:

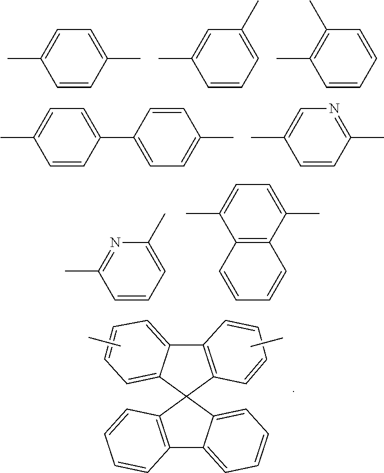

6. The organic electroluminescence element according to claim 1, wherein the compound represented by General Formula (2) is a compound represented by General Formula 15a-3. 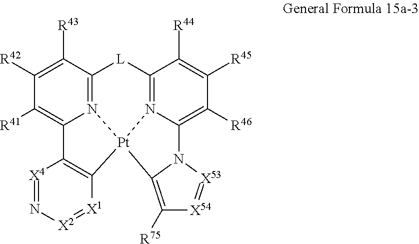
where X¹, X² and X⁴ each independently represent a carbon atom or a nitrogen atom; R⁴¹, R⁴², R⁴³, R⁴⁴, R⁴⁵ and R⁴⁶ each independently represent a hydrogen atom or a substituent; X⁵³ and X⁵⁴ each independently represent a carbon atom or a nitrogen atom, the number of nitrogen atoms contained in a 5-membered ring skeleton containing X⁵³ and X⁵⁴ is 1 or 2; R⁷⁵ represents a hydrogen atom or a substituent; and L represents a single bond or a divalent linking group.

7. The organic electroluminescence element according to claim 1, wherein the light emitting layer contains at least one of a metal complex compound containing a polydentate ligand having a partial structure represented by General Formula (2) and a platinum complex compound containing a tetradentate ligand represented by General Formula 15a-3.

8. The organic electroluminescence element according to claim 1, wherein the light emitting layer contains at least one of a metal complex compound containing a polydentate ligand having a partial structure represented by General Formula (2), a platinum complex compound containing a tetradentate ligand represented by General Formula 15a-3, and at last one host material.

9. The organic electroluminescence element according to claim 8, wherein the at least one host material is hole-transportable.

10. The organic electroluminescence element according to claim 1, wherein the nitrogen-containing heterocyclic derivative functions as at least one of an electron injection material and an electron transporting material.

11. The organic electroluminescence element according to claim 1, wherein the layer containing the nitrogen-containing heterocyclic derivative contains a reducing dopant.

12. The organic electroluminescence element according to claim 11, wherein the reducing dopant is at least one selected from alkali metals, alkaline earth metals, rare earth metals, alkali metal oxides, alkali metal halides, alkali earth metal oxides, alkali earth metal halides, rare earth metal oxides, rare earth metal halides, alkali metal organic complexes, alkali earth metal organic complexes, and rare earth metal organic complexes.
